(19) United States
(12) Patent Application Publication
(10) Pub. No.: US 2026/0003296 A1
(43) Pub. Date: Jan. 1, 2026

(54) METHOD FOR DETECTING DEFECTS IN A PHOTOLITHOGRAPHY MASK FROM AN AERIAL IMAGE

(71) Applicant: Carl Zeiss SMT GmbH, Oberkochen (DE)

(72) Inventors: Martin van Driel, Muenchen (DE); Bjoern Barz, Jena (DE); Bjoern Brauer, Magstadt (DE); Alexander Freytag, Erfurt (DE); Bjoern Froehlich, Jena (DE); Dirk Seidel, Jena-Leutra (DE)

(21) Appl. No.: 19/245,927

(22) Filed: Jun. 23, 2025

(30) Foreign Application Priority Data
Jun. 27, 2024 (DE) 102024118188.5

(51) Int. Cl. G03F 7/00

(52) U.S. Cl. CPC G03F 7/70666; G03F 7/7065; G03F 7/706841

(57) ABSTRACT

The invention relates to a method for detecting defects in a photolithography mask, the method comprising: i. Acquiring an aerial image of the photolithography mask; ii. Obtaining an underlying design of the photolithography mask; iii. Generating a plausible design of the acquired aerial image by solving an optimization problem that minimizes the deviation of a simulated aerial image of the plausible design from the acquired aerial image; and iv. Detecting defects in the photolithography mask by comparing the underlying design to the plausible design. The invention also relates to a corresponding system for detecting defects.

### CROSS-REFERENCE TO RELATED APPLICATION

This application claims benefit under 35 U.S.C. § 119 (a) of German Patent Application No. 10 2024 118 188.5, filed on Jun. 27, 2024, which is incorporated herein by reference in its entirety.

### TECHNICAL FIELD

The invention relates to methods and systems for quality control and quality assurance in photolithography masks, more specifically to a method and a corresponding system for defect detection in an aerial image of a photolithography mask. The methods and systems can be utilized for quantitative metrology, process monitoring, defect detection and defect review in photolithography masks.

### BACKGROUND

Semiconductor manufacturing involves precise manipulation, e.g., etching, of materials such as silicon or oxide at very fine scales in the range of nm. Therefore, a quality management process comprising quality assurance and quality control is important for ensuring high quality standards of the manufactured wafers. Quality assurance refers to a set of activities for ensuring high-quality products by preventing any defects that may occur in the development process. Quality control refers to a system of inspecting the final quality of the product. Quality control is part of the quality assurance process.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithographic masks or templates for nanoimprint photolithography with ever smaller structures or pattern elements. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

On account of the tiny structure sizes of the pattern elements of photolithographic masks or templates, it is not possible to exclude errors during mask or template production. The resulting defects can, for example, arise from degeneration of photolithography masks or particle contamination. Of the various defects occurring during semiconductor structure manufacturing, photolithography related defects make up nearly half of the number of defects. Hence, in semiconductor process control, photolithography mask inspection, review, and metrology play a crucial role to monitor systematic defects. Defects detected during quality assurance processes can be used for root cause analysis, for example, to modify or repair the photolithography mask. The defects can also serve as feedback to improve the process parameters of the manufacturing process, e.g., exposure time, focus variation, etc.

Each defect in the photolithography mask can lead to unwanted behavior of the produced wafer, or a wafer can be significantly damaged. Therefore, each defect must be found and repaired if possible and necessary. Reliable and fast defect detection methods are, therefore, important for photolithography masks.

In order to analyze large amounts of data requiring large amounts of measurements to be taken, machine learning methods can be used. Machine learning is a field of artificial intelligence. Machine learning methods generally build a parametric machine learning model based on training data consisting of a large number of samples. After training, the method is able to generalize the knowledge gained from the training data to new previously unencountered samples, thereby making predictions for new data. There are many machine learning methods, e.g., linear regression, k-means, support vector machines, decision trees, random forests, neural networks or deep learning approaches.

Deep learning is a class of machine learning that uses artificial neural networks with numerous hidden layers between the input layer and the output layer. Due to this complex internal structure the networks are able to progressively extract higher-level features from the raw input data. Each level learns to transform its input data into a slightly more abstract and composite representation, thus deriving low and high level knowledge from the training data. The hidden layers can have differing sizes and tasks such as convolutional or pooling layers.

Methods for the automatic detection of defects in photolithography masks include defect detection algorithms, which are often based on a die-to-die or die-to-database principle. The die-to-die principle compares an imaging dataset of a photolithography mask to a reference dataset comprising the same structures obtained from a different portion of the same photolithography mask or from a different photolithography mask. The discovered deviations are treated as defects. However, this method requires the availability and time-consuming scanning of two corresponding portions of photolithography masks and exact knowledge about their relative position. In addition, it fails in case of repeater defects.

The die-to-database principle compares an imaging dataset of a photolithography mask with a reference dataset from a database, e.g., a simulated image, a design, a CAD file or a model of the photolithography mask, thereby discovering deviations from the ideal data. Unexpected patterns in the imaging dataset are detected due to large differences. Repeater defects can be handled. However, the comparison of an imaging dataset, in particular an aerial image, to a reference dataset is difficult due to different acquisition parameters, styles and qualities of the images.

Therefore, it is an aspect of the invention to improve the accuracy of die-to-database methods for defect detection in photolithography masks. In particular, it is an aspect to improve the accuracy of a comparison between an aerial image and a corresponding design of a photolithography mask. It is another aspect of the invention to reduce the computation time for defect detection in photolithography masks.

The aspects are achieved by the invention specified in the independent claims. Advantageous embodiments and further developments of the invention are specified in the dependent claims.

### SUMMARY

Embodiments of the invention concern methods and systems for defect detection in aerial images of photolithography masks.

A first embodiment involves a method for detecting defects in a photolithography mask, the method comprising: i. acquiring an aerial image of the photolithography mask using an optical system; ii. obtaining an underlying design of the photolithography mask; iii. generating a plausible design by solving an optimization problem that minimizes the deviation of a simulated aerial image of the plausible design from the acquired aerial image, wherein the simulated aerial image simulates the application of the optical system to the plausible design; and iv. detecting defects in the photolithography mask by comparing the underlying design to the plausible design.

Another embodiment involves a method for detecting defects in a photolithography mask, the method comprising: i. acquiring an aerial image of the photolithography mask using an optical system; ii. obtaining an underlying design of the photolithography mask; iii. generating a plausible design by solving an optimization problem, such that the deviation of a simulated aerial image of the plausible design from the acquired aerial image is smaller than the deviation of a simulated aerial image of the underlying design from the acquired aerial image, wherein the simulated aerial image of the plausible design simulates the application of the optical system to the plausible design, and wherein the simulated aerial image of the underlying design simulates the application of the optical system to the underlying design; and iv. detecting defects in the photolithography mask by comparing the underlying design to the plausible design.

The term “defect” refers to a localized deviation of an integrated circuit pattern in a photolithography mask or on a wafer from an a priori defined norm of the integrated circuit pattern. For instance, a defect of an integrated circuit pattern, e.g., of a semiconductor structure, can result in malfunctioning of an associated semiconductor device. Depending on the detected defect, for example, the photolithography process can be improved, or photolithography masks or wafers can be repaired or discarded. The norm of the integrated circuit pattern can be defined by one or more corresponding reference objects or reference datasets, e.g., by design datasets, simulated datasets or acquired defect-free datasets.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

An optimization problem comprises an objective function that is to be maximized or minimized. The optimization problem can also comprise constraints. Solving the optimization problem means applying some kind of mathematical optimization method. The mathematical optimization method computes a point with an objective function value that is expected to be better than the objective function values for multiple other points. Solving the optimization problem can, for example, mean computing the global optimum or a local optimum of the objective function. The mathematical optimization method can comprise computing an analytical solution or applying an iterative method such as gradient descent, a Simplex method, a variational approach, a combinatorial optimization approach, etc. Iterative methods can use an initial solution and iteratively adapt the initial solution until a convergence criterion is met or for a predefined number of iterations. A mathematical optimization method can also comprise computing the output of a model, which was trained to optimize an objective function for a given input, e.g., applying a machine learning model to the input that was trained to minimize a loss function. The model is, thus, trained to directly predict a solution to the optimization problem.

An aerial image indicates the radiation intensity distribution of a photolithography system in a wafer plane for a given photolithography mask. The aerial image is, thus, used to simulate the structures on the surface of a wafer when printing the wafer using the photolithography mask in the photolithography system. A wafer plane refers to a plane within the resist on top of the wafer in the photolithography system. An aerial image can also be generated by applying a mask inspection system or an optical mask qualification system to a photolithography mask. An aerial image can also be simulated using a design of a photolithography mask and an aerial image simulation method.

An aerial image can refer to the aerial image of a complete photolithography mask, or it can refer to the aerial image of a section of the photolithography mask. A design can refer to the design of a complete photolithography mask, or it can refer to the design of a section of the photolithography mask.

An optical system refers to a system that uses light to inspect a photolithography mask or wafer or to generate an integrated circuit pattern on a wafer. Optical systems comprise, for example, inspection systems, optical mask qualification systems, photolithography systems and metrology systems.

A photolithography system refers to a system that is used to fabricate integrated circuits. To this end, during the photolithography process a photolithography mask is irradiated with light to transfer the integrated circuit pattern via the photolithography mask to a substrate by use of a light-sensitive chemical process.

An inspection system refers to an optical system used to detect defects in a photolithography mask by acquiring an aerial image of the photolithography mask.

An optical mask qualification system refers to a system that is used to acquire an aerial image of a portion of a photomask, in particular of potential defects detected using an inspection system. The optical mask qualification system emulates settings of a photolithography system, e.g. illumination and imaging parameters, to examine the effect of a potential defect on a printed wafer, to verify that photolithography masks are defect-free or whether a repair attempt has been successful.

Parameters describing an optical system comprise, for example,
Illumination parameters describing the illumination setting of the photolithography system, comprising the distribution and intensities of different illumination angles, e.g., an annular illumination setting, a dipole illumination setting, a quasar illumination setting, etc.,
imaging parameters such as the numerical aperture of the photolithography system and the magnification of the photolithography system, obscurations, aberrations, apodizations or distortions,
design parameters such as parameters describing the material of the photolithography mask, e.g., layer thicknesses, refractive indices of different layers, etc.

A design of a photolithography mask refers to a representation of the photolithography mask or a section thereof. The design can, for example, comprise a computer readable file, such as a CAD file or a graphic design system (GDS) file, or a technical drawing, a set of polygons representing the structures of the photolithography mask or a section thereof. A design of a photolithography mask can comprise material information, e.g., complex refractive indices of materials contained in the photolithography mask, electric permittivities, magnetic permeabilities, or derived representations. A design of a photolithography mask can comprise parameters describing dimensions of structures in the photolithography mask, e.g., the thicknesses of the layers in the multilayer of an EUV mask or the thickness of absorber layers, or the dimension of the absorber structures.

A design of a photolithography mask can comprise parameters describing the location of structures in the photolithography mask, e.g., the location of absorber structures or layers in the multilayer. A design of a photolithography mask can comprise parameters describing the shape of structures in the photolithography mask, e.g., the shape of the absorber structures such as side wall angles or corner rounding, etc. A design of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. The properties of the photolithography mask can comprise material properties, e.g., refractive indices, electric permittivities, magnetic permeabilities, or derived representations. A design of a photolithography mask can comprise descriptions of the structures within the photolithography mask, e.g., in the form of curves, contours, polygons, Splines, NURBS, Bézier curves, etc.

A design can refer to the design of a complete photolithography mask, or it can refer to the design of a section of the photolithography mask.

An “underlying design” of a photolithography mask refers to a design that describes the structures in the photolithography mask, e.g., a model such as a CAD model. An underlying design can be provided for a photolithography mask, or it can be derived from an image of the photolithography mask, e.g., using image processing or machine learning methods.

A “plausible design” of an aerial image refers to a design that can be used by an aerial image simulation method to simulate the aerial image. A design is a plausible design of an aerial image, if the aerial image is a plausible result of an aerial image simulation method applied to the plausible design. The plausible design can be an underlying design of a photolithography mask that could be used to generate the aerial image, e.g., using an aerial image measurement system for a set of parameters.

A simulated aerial image can be simulated by an aerial image simulation method. An aerial image simulation method simulates the generation of an aerial image of a photolithography mask from a design of the photolithography mask in an optical system. The aerial image simulation method can use physics-based models, e.g., of the photolithography mask and/or of the propagation of electromagnetic waves through the photolithography mask. The aerial image simulation method can also use non-physics-based models, e.g., machine learning models that are trained using training data.

In a preferred example, the underlying design and the plausible design are represented in a vector format. A vector format of a design represents the structures of the design by continuous coordinates and connections between them. The advantage of using a vector format is a very accurate representation of the structures in the design due to the continuous coordinates in contrast to the limited accuracy due to the pixel size in a raster image. In addition, measurements of the structures can be determined with increased accuracy, e.g., distances between structures.

In another example, the underlying design and the plausible design are represented by non-binary images. Non-binary images can be used to represent structures in the photolithography mask with sub-pixel accuracy. In this way, structure boundaries can, for example, be located between pixels. Thus, the accuracy of the method is improved.

According to an aspect of the invention, the underlying design of the photolithography mask is generated from the acquired aerial image, e.g., using image processing or machine learning. Thus, the method for detecting defects can even be used if no underlying design is available for the photolithography mask.

In a preferred example, the defects in the photolithography mask are detected in step iv. by comparing the underlying design to the plausible design in a mathematical space, e.g., a Fourier space, a polygon space or a wavelet space. To this end, the underlying design and the plausible design can be transformed into the mathematical space. Alternatively, the underlying design and the plausible design can directly be represented in a mathematical space. Distance measures can be defined in the mathematical space to measure a distance between the underlying design and the plausible design. In this way, the comparison can be simplified and the accuracy of the measured distance can be improved. In addition, the comparison can be aimed at or limited to specific details of the designs that can be represented particularly well in a specific mathematical space.

According to an example of the invention, solving the optimization problem in step iii. comprises applying a machine learning model to the acquired aerial image, wherein the machine learning model is trained to map an acquired aerial image to a plausible design of the acquired aerial image. The machine learning model allows for an accurate and fast computation of the plausible design from the acquired aerial image. The accuracy is determined by the selected training data. The computation time is very fast, since only a forward pass of the trained machine learning model is required during inference.

According to an example of the invention, solving the optimization problem in step iii. comprises generating a plausible design by modifying the underlying design in order to minimize the deviation of the acquired aerial image from a simulated aerial image, wherein the simulated aerial image is obtained by applying an aerial image simulation method to a design. The design yielding the minimum deviation of the corresponding simulated aerial image from the acquired aerial image is the plausible design that is obtained by solving the optimization problem. Solving an optimization problem in this way to generate the plausible design increases the accuracy of the plausible design by minimizing the deviation of the simulated aerial image from the acquired aerial image. In this way, a plausible design can be obtained that could be used to approximately generate the acquired aerial image.

In a preferred example, a parametric representation of the underlying design is optimized by solving the optimization problem. In this way, a flexible representation of the underlying design can be obtained that can be modified to obtain the plausible design. In an example, the parametric representation describes structure boundaries of the underlying design, e.g., geometric shapes, contours, or polygons. In this way, a particularly simple and flexible parametric representation of low complexity is obtained that is well suited for optimization. In particular, the parametric representation can comprise contours represented by graphs containing nodes and edges. The location of the nodes and edges can be optimized by solving the optimization problem.

According to an aspect of the first embodiment, the optimization problem comprises parameters that describe a modification of the underlying design, and the optimization problem imposes a sparsity constraint on these parameters. In this way, the accuracy of the optimized parameters and, thus, of the plausible design is improved. In addition, the plausible design is less susceptible to noise in the acquired aerial image.

In an example, the aerial image simulation method comprises the use of a physical model for generating an aerial image from the plausible design. The use of a physical model leads to highly accurate simulations that adhere to the laws of physics.

According to an example, the aerial image simulation method comprises a machine learning model. In this way, the aerial image simulation method is improved, since machine learning models directly and automatically learn important correlations from training data without requiring hand-crafted, rule-based, usually error-prone programs. In addition, the machine learning model can be used to improve the accuracy of other methods used in the aerial image simulation method. It, thus, allows for using less complex methods of lower computation time for generating an aerial image from the plausible design.

In a preferred example, the aerial image simulation method comprises a physical model and a machine learning model for generating an aerial image from the plausible design. The machine learning model can be applied subsequently to the physical model. In this way, the machine learning model can increase the accuracy of the output of the physical model. At the same time, it allows for using less complex physical models, since the result is processed further by the machine learning model.

In an example, the aerial image simulation method comprises a machine learning model that maps a design to an aerial image. Since machine learning models directly learn important correlations from training data, the aerial image simulation method is highly accurate. In addition, the computation time is low as only a single forward pass is required at inference time.

According to a preferred example of the invention referred to as not quite rigorous (NQR) in the following, the aerial image simulation method generates an aerial image from the plausible design under illumination of a corresponding photolithography mask by incident electromagnetic waves in an optical system, in particular in an inspection system, in a photolithography system or in an optical mask qualification system, and comprises: a) Approximately simulating the propagation of the incident electromagnetic waves within a first section of the photolithography mask that comprises multiple structures; b) Simulating the propagation of the simulated electromagnetic waves from step a) within a second section of the photolithography mask analytically or numerically; c) Simulating a representation of an electromagnetic near field of the design by propagating the simulated electromagnetic waves from step b) to a near field plane; and d) Generating an aerial image from the plausible design by applying a simulation of an imaging process of the optical system to the representation of the electromagnetic near field. For example, the first section of an EUV photolithography mask can contain absorber and non-absorber structures, whereas the second section of the EUV photolithography mask can contain a multilayer as further described below. This aerial image simulation method yields aerial images of higher accuracy and at lower computation times than standard aerial image simulation methods and, thus, also increases the accuracy of the detected defects.

The electromagnetic near field is computed in different ways within the first section of the photolithography mask and within the second section of the photolithography mask. Within the first section several assumptions described below can be made in the photolithography setting, which allow for a simplified and fast computation of the propagation of the electromagnetic waves within the first section. The propagation of the electromagnetic waves within the first section is computed by use of a wave propagation method, which takes into account the inhomogeneity of the medium within the first section of the photolithography mask. Within the second section, the propagation of the electromagnetic waves is computed analytically or numerically. In this way, a highly accurate approximation of the propagation of the electromagnetic waves within the photolithography mask is obtained, requiring computation times several magnitudes below rigorous simulation methods. Thus, the simulation of electromagnetic near fields and aerial images within industry applications becomes feasible.

The design of the photolithograph mask preferably describes the photolithography mask at least partially in a dimension orthogonal to a base plane of the photolithography mask. The design of the photolithography mask can comprise one or more different sections of the photolithography mask or parts thereof, for example the first section and/or the second section. The one or more different sections can be arranged at different depths with respect to the normal of the surface.

The first section of the photolithography mask comprises multiple structures. These structures can be arranged in a design that determines the patterns imprinted on the wafer during the printing process. The design can comprise structures and non-structures, in particular absorber structures and non-absorber structures. The second section of the photolithography mask can contain a mask carrier that can comprise one or multiple layers of one or more materials. The structures and the non-structures can be deposited on the mask carrier. The mask carrier can comprise a substrate layer. The second section can be configured to transmit the incident electromagnetic waves (for transmission-based photolithography masks) or it can be configured to reflect the incident electromagnetic waves (for reflection-based photolithography masks). The first section can be directly adjacent to the second section of the photolithography mask. Thus, the first section and the second section can have a common boundary, e.g., a boundary plane. The mask carrier in the photolithography mask can be delimited by the boundary plane and a base plane. The boundary plane can be a surface plane of the mask carrier. The base plane is preferably parallel to the boundary plane. The base plane can delimit the second section from the outside. It can form an interface between the mask carrier and the outside of the photolithography mask through which the electromagnetic waves propagate. The structures in the first section of the photolithography mask can be delimited by the boundary plane and a structure plane. The structure plane can delimit the first section of the photolithography mask from the outside. The structure plane can contain the portion of the surface of the structures, which is facing away from the boundary plane. Preferably, the structure plane is parallel to the boundary plane. The first section of the photolithography mask can extend between the structure plane and the boundary plane and can be delimited by these planes. The second section of the photolithography mask can extend between the boundary plane and the base plane. It can be delimited by the boundary plane and the base plane. The second section can contain a stack of homogeneous parallel layers. Homogeneous means that the material properties do not change within a layer. Other constructions of photolithography masks containing a first section and a second section can also be used.

An electromagnetic near field indicates the distribution of the electromagnetic waves in a near field plane. The near field plane can be located next to a structure plane of the photolithography mask that delimits the first section of the photolithography mask from the outside. Preferably, the near field plane is parallel to the structure plane of the photolithography mask. The near field plane can be located anywhere between the structure plane and a wafer plane, for example, the near field plane can be located at a distance between 0 and 1000 nm from the structure plane, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane and the structure plane are identical. The near field plane could, in principle, also lie within the first section, within the second section, on the structure plane, on the base plane, or outside of the photolithography mask at the side of the base plane of the photolithography mask, for example in case the electromagnetic waves are re-propagated back into the photolithography mask after propagation through the first section.

A representation of an electromagnetic (near) field can refer to the (complex) electric field E or the (complex) scattered electric field E_{sc}=E−E_{inc}, where E_{inc} denotes the incident electric field. A complex electromagnetic field can be represented for example, in terms of the real and imaginary part, or the amplitude and phase, etc. A representation of an electromagnetic field can refer to the (complex) magnetic field H or the (complex) scattered magnetic field H_{sc}=H−H_{inc}, where H_{inc} denotes the incident magnetic field. A representation of an electromagnetic field can comprise measurements derived from the electromagnetic field, e.g., diffraction orders, the spectrum, the far field or the intensity field, etc. A representation of an electromagnetic field within the photolithography mask can refer to the electromagnetic field within the photolithography mask, to a section of the electromagnetic field within the photolithography mask, to an electromagnetic field next to the photolithography mask, e.g., a near field, etc. A representation of an electromagnetic field can comprise representations of the electromagnetic field for different spatial directions. For example, a representation of an electromagnetic field can comprise a 2D or 3D image containing one, two or more channels, such that the 2D or 3D image comprises a representation of the electromagnetic field in each spatial direction, e.g., the complex electric field in x and y or in x, y and z directions yielding a 2D or 3D image with four or six channels.

According to a first example of the embodiment, the propagation of the incident electromagnetic waves within the first section of the photolithography mask in step a) is approximately simulated using a Helmholtz equation. In this way, the approximation is simplified and, thus, the complexity and the computation time reduced.

According to a second example of the embodiment, the propagation of the incident electromagnetic waves within the first section of the photolithography mask in step a) is approximately simulated using a machine learning model. By using a machine learning model, the computation time can be strongly reduced, as after training a single and fast forward pass is sufficient to compute the propagation of the incident electromagnetic waves.

According to an aspect of the first example, the Helmholtz equation is approximated using a forward Helmholtz equation. In this way, the approximation is simplified and, thus, the complexity and the computation time reduced.

The forward Helmholtz equation can be solved using a beam propagation method. In this way, the approximation is simplified and, thus, the complexity and the computation time reduced.

In a preferred embodiment, the forward Helmholtz equation is solved using a wave propagation method that approximately describes the propagation of electromagnetic waves through an inhomogeneous medium. By using the wave propagation method, the forward Helmholtz equation is solved quickly, thereby reducing the computation time of the method. Furthermore, by taking into account the inhomogeneity of the first section of the photolithography mask, e.g., due to different materials in absorber structures and non-absorber structures, the wave propagation is simulated with high accuracy.

According to an aspect of the first embodiment, after step i., one or more regions of interest are identified in the acquired aerial image that contain possible defect candidates, and wherein steps ii. to iv. are only applied to the one or more regions of interest. In this way, the computation time of the defect detection method can be strongly reduced as large parts of a photolithography mask usually do not contain any defect and can be excluded from further investigations using a fast defect detection method with a low false negative rate. Alternatively, user input can be used to define regions of interest. The detected potential defects can be examined using the method according to the invention in a subsequent processing step. In this way, also the accuracy of the defect detection method can be improved.

A computer implemented method for training a machine learning model according to a second embodiment of the invention comprises training any of the machine learning models according to an example or aspect of the first embodiment of the invention.

A system for detecting defects in a photolithography mask according to a third embodiment of the invention comprises: an optical system for acquiring an aerial image of the photolithography mask; and a data analysis device comprising at least one memory and at least one processor configured to perform the steps of the method for detecting defects in a photolithography mask according to any of the examples or aspects of the first embodiment.

The invention described by embodiments, examples and aspects is not limited to the embodiments, examples and aspects, but can be implemented by those skilled in the art by various combinations or modifications thereof.

### BRIEF DESCRIPTION OF DRAWINGS

FIG. 1 illustrates an exemplary transmission-based photolithography system, e.g., a deep ultraviolet (DUV) photolithography system;

FIG. 2 illustrates an exemplary reflection-based photolithography system, e.g., an extreme ultra-violet light (EUV) photolithography system;

FIG. 3 illustrates a die-to-database method for defect detection that compares an aerial image of a photolithography mask to a design of the corresponding photolithography mask to detect defects;

FIG. 4 shows a flowchart of a method for detecting defects in a photolithography mask according to a first embodiment of the invention;

FIG. 5 illustrates an exemplary application of the method in FIG. 4;

FIGS. 6A and 6B illustrate solving an optimization problem by applying a machine learning model that is trained to map an acquired aerial image to a plausible design of the acquired aerial image;

FIGS. 7A-7C illustrate solving an optimization problem that comprises minimizing the deviation of a simulated aerial image of the plausible design from the acquired aerial image, wherein the plausible design is obtained by modifying the underlying design of the acquired aerial image;

FIG. 8 illustrates the adaptation of a parametric representation of a design to increase its flexibility for defect detection;

FIG. 9A shows a flowchart of a not quite rigorous method for generating an aerial image of a photolithography mask;

FIG. 9B illustrates the propagation of incoming electromagnetic waves through a transmission-based photolithography mask;

FIG. 9C shows a flowchart of the not quite rigorous method for generating an aerial image of a transmission-based photolithography mask;

FIG. 9D illustrates the propagation of incoming electromagnetic waves through a reflection-based photolithography mask;

FIG. 9E shows a flowchart of the not quite rigorous method for generating an aerial image of a reflection-based photolithography mask;

FIG. 9F shows a flowchart of an example of the not quite rigorous method for generating an aerial image of a photolithography mask including an additional characteristic function step;

FIG. 9G illustrates the dependency of the phase shift vector α on the angle ϕ of the incoming electromagnetic waves;

FIG. 9H illustrates the steps of the not quite rigorous method for generating an aerial image of a photolithography mask according to an example;

FIG. 10 illustrates an aerial image simulation method that comprises a machine learning model; and

FIG. 11 illustrates a system for detecting defects in a photolithography mask according to a third embodiment of the invention.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

The methods and systems herein can be used with a variety of photolithography systems, e.g., transmission-based photolithography systems 10 or reflection-based photolithography systems 10′.

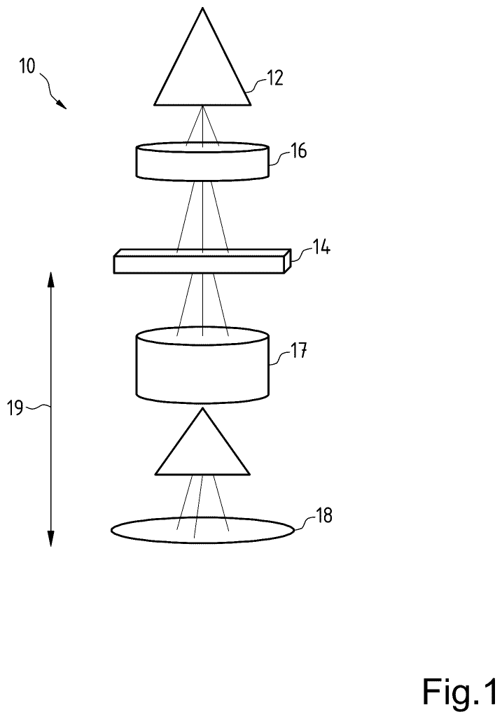

FIG. 1 illustrates an exemplary transmission-based photolithography system 10, e.g., a DUV photolithography system. Major components are a radiation source 12, which may be a deep-ultraviolet (DUV) excimer laser source, imaging optics which, for example, define the partial coherence and which may include optics that shape radiation from the radiation source 12, a photolithography mask 14, illumination optics 16 that illuminate the photolithography mask 14 and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate and the last element of the projection optics 17, and Gmax is the largest angle of the beam exiting from the projection optics 17 that can still impinge on the wafer plane 18.

In the present document, the terms “radiation” or “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 3-100 nm).

Illumination optics 16 may include optical components for shaping, adjusting and/or projecting radiation from the radiation source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

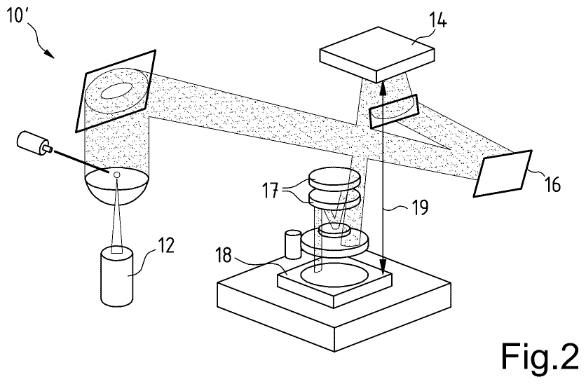

FIG. 2 illustrates an exemplary reflection-based photolithography system 10′, e.g., an extreme ultraviolet light (EUV) lithography system. Major components are a radiation source 12, which may be a laser plasma light source, illumination optics 16 which, for example, define the partial coherence and which may include optics that shape radiation from the radiation source 12, a photolithography mask 14, and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin (Gmax), wherein n is the refractive index of the media between the substrate and the last element of the projection optics 17, and Gmax is the largest angle of the beam exiting from the projection optics 17 that can still impinge on the wafer plane 18.

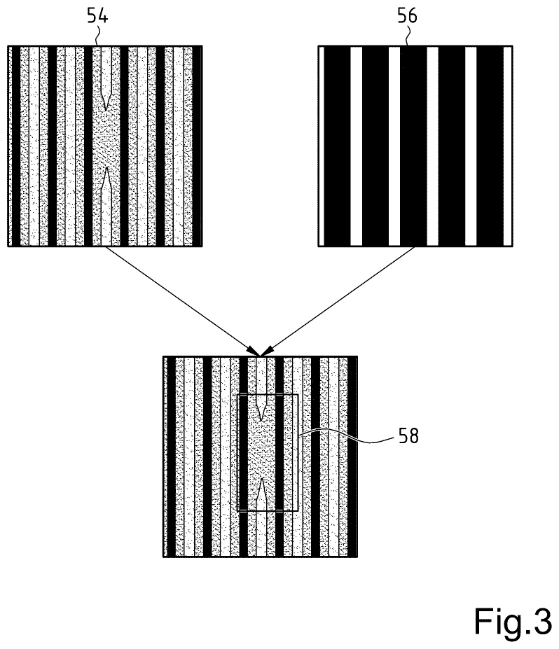

FIG. 3 illustrates a state-of-the-art die-to-database method for defect detection that compares an aerial image 54 of a photolithography mask 14 to a design 56 of the corresponding photolithography mask 14 to detect defects 58. However, the appearance of the aerial image 54 and the design 56 strongly differs, thus making a direct comparison difficult and detected defects 58 less reliable.

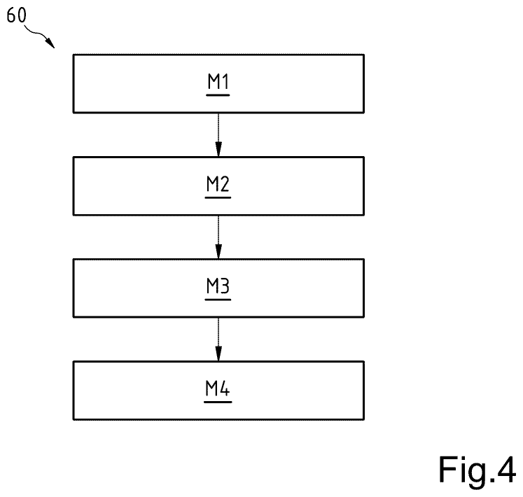

To improve the reliability of the detected defects, FIG. 4 shows a flowchart of a method 60 for detecting defects in a photolithography mask according to a first embodiment of the invention. The method comprises: acquiring an aerial image of the photolithography mask using an optical system in a step M1; obtaining an underlying design of the photolithography mask in a step M2; generating a plausible design of the acquired aerial image by solving an optimization problem that minimizes the deviation of a simulated aerial image of the plausible design from the acquired aerial image, wherein the simulated aerial image simulates the application of the optical system to the plausible design in a step M3; and detecting defects in the photolithography mask by comparing the underlying design to the plausible design in a step M4. After optimization, the deviation of a simulated aerial image of the plausible design from the acquired aerial image is smaller than the deviation of a simulated aerial image of the underlying design from the acquired aerial image.

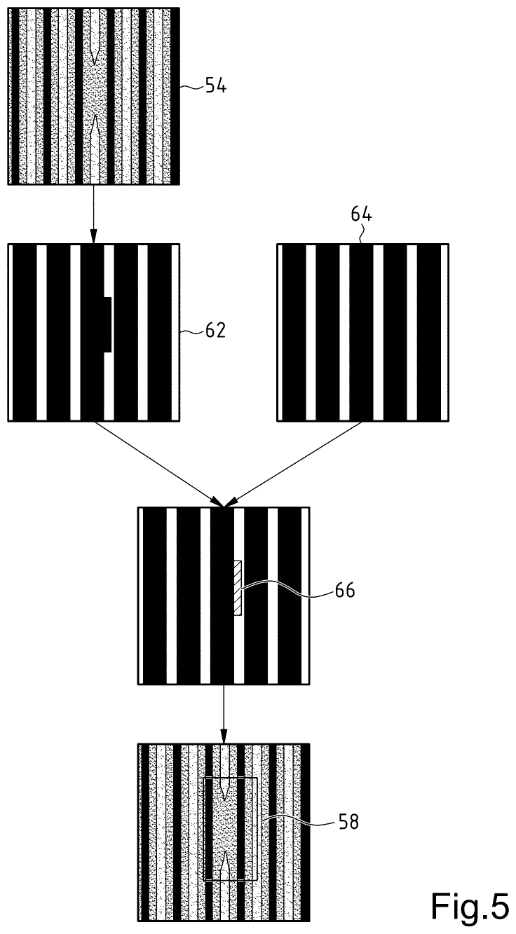

FIG. 5 illustrates an exemplary application of this method. An aerial image 54 is acquired of a photolithography mask 14 in step M1. The aerial image 54 can, for example, be acquired using an aerial image measurement system that simulates the intensity distribution in a wafer plane for a photolithography mask illuminated by incident electromagnetic waves. The aerial image 54 can also be acquired using a metrology system.

An underlying design 64 of the photolithography mask 14 is obtained in step M2. For example, the underlying design 64 can be loaded from a database, obtained from a designer of the photolithography mask, or derived from an aerial image of the photolithography mask using image processing methods.

A plausible design 62 of the acquired aerial image 54 is generated such that the acquired aerial image 54 is a plausible result of an aerial image simulation method applied to the plausible design 62 in step M3. Thus, the plausible design 62 is generated in such a way that the acquired aerial image 54 could be generated from the plausible design 62 using some aerial image acquisition method or system and a set of corresponding parameters.

The plausible design 62 is compared to an underlying design 64 of the photolithography mask 14 in step M4. For example, the differences 66 between the underlying design and the plausible design can be computed, e.g., using a difference image in case the underlying design and the plausible design are represented by images, e.g., non-binary images, or, for example, as difference vectors in case the underlying design and the plausible design are represented in a vector format. The locations of the differences 66 correspond to the locations of defects 58 in the photolithography mask. A machine learning model can be used to detect defects 58 directly from the underlying design 64 and the plausible design 62, or from a representation indicating the differences between the underlying design and the plausible design, e.g., from a difference image or from difference vectors.

According to an example of the first embodiment, the defects 58 in the photolithography mask 14 are detected in step iv. by comparing the underlying design 64 to the plausible design 62 in a mathematical space. To this end, the underlying design 64 and the plausible design 62 can be transformed into a different mathematical space, e.g., into a Fourier space, a polygonal space, a wavelet space, a CAD space, etc. Alternatively, the underlying design 64 and the plausible design 62 can directly be represented in a mathematical space without requiring a transformation. Distance measures can be defined in the mathematical space to measure the deviation of the underlying design from the plausible design.

Various methods for quantitatively measuring contour or shape distances in a mathematical space are known in the literature. For example, the deviation of two contours, one of the underlying design 64 and the other of the plausible design 62, e.g., in a polygonal or CAD space, can be measured in different ways. For example, a bending energy measures the amount of energy required to transform one contour into the other. For example, the deviations of the two contours can be measured by computing the maximum, average or median distance between each contour point of the first contour and the closest contour point of the second contour. Alternatively, a Hausdorff distance can be used to measure deviations between two contours. Alternatively, the areas defined by the contours can be compared, e.g., the overlapping area or the non-overlapping area can serve for measuring contour deviations. In case the underlying design 64 and the plausible design 62 are represented by images, e.g., non-binary images, the overlapping area or the non-overlapping area of structures can be used to measure the deviations. Distances between contours or shapes can be measured in the Fourier space, e.g., by computing a difference vector of Fourier coefficients. Distance measures in other mathematical spaces can be defined with respect to the underlying bases, e.g., a wavelet basis or a principal component basis. For example, difference vectors of the coefficients with respect to the bases can be used as distance measures. The underlying design 64 and/or the plausible design could also be transformed into contours or areas, that can be compared using any of the measures above.

In a preferred example of the first embodiment, the underlying design 64 and the plausible design 62 are represented in the same way, e.g., they share the same format, type of representation, color or grey value space, etc. By using the same representation, the comparability of the designs is ensured yielding improved comparison and defect detection results. Each type of design can have different advantages that allow for a specifically accurate comparison.

For example, the underlying design 64 and the plausible design 62 can be represented in a vector format. The vector format is based on the mathematics of coordinate geometry, in which shapes are defined as a set of points in a two- or three-dimensional cartesian coordinate system. Because almost all shapes consist of an infinite number of points, the vector format defines a limited set of geometric primitives that can be specified using a finite sample of salient points called vertices. For example, a square can be unambiguously defined by the locations of three of its four corners, from which the software can interpolate the connecting boundary lines and the interior space. Because it is a regular shape, a square could also be defined by the location of one corner, a size, and a rotation angle. The fundamental geometric primitives of the vector format comprise points, line segments, polygons, parametric shapes in two or three dimensions such as circles, ellipses, squares, spheres, super-ellipses, etc., parametric curves, in which polylines or polygons are augmented with parameters to define a non-linear interpolation between vertices, such as circular arcs, cubic Splines, Bézier curves, etc., and three-dimensional surfaces usually defined as a connected set of polygons or as parametric surfaces, e.g., polygon meshes or non-uniform rational basis splines (NURBS).

In another example, the underlying design 64 and the plausible design 62 are represented by non-binary images. The underlying design 64 and the plausible design 62 can also be represented by images that share the same color or grey value space or color or grey value range. In another example, the underlying design 64 and the plausible design 62 are represented in a CAD format, e.g., gdsll, oasis, svg, dxf, etc. The underlying design 64 and the plausible design 62 can be represented by geometrical structures, e.g., polygons, circles, ellipses, contours, etc. The geometrical structures can be described using coordinates such as corner points or center points, lengths, angles, directions, axes, etc. The underlying design 64 and the plausible design 62 can be represented by contours delineating the structures in the design, e.g., by lines, curves, or graphs containing nodes and edges. In another example, the underlying design 64 and the plausible design 62 are represented by Fourier descriptors.

In the following, obtaining the underlying design and the plausible design from aerial images will be described in detail.

The underlying design is, preferably, provided along with the photolithography mask. According to an example of the first embodiment, the underlying design of the photolithography mask can also be generated from an image, in particular from an aerial image, in particular from a defect-free aerial image, of the photolithography mask, or from a golden reference image of the photolithography mask. To this end, image processing methods can be used, e.g., image segmentation, pattern matching, thresholding, contour extraction, edge detection, etc. These methods can, for example, be used to find structures or patterns in the image, in particular in the aerial image, that correspond to structures in the underlying design, e.g., repetitive structures. These structures can, for example, be represented by polygons in the underlying design, e.g., circles can represent memory holes, etc. Apart from or in addition to image processing methods, machine learning methods can be used to map an image, in particular an aerial image, to an underlying design. The machine learning methods can be trained using pairs of images, in particular of aerial images, of photolithography masks and corresponding underlying designs in the required representation as training data. Deep learning methods such as CNNs, U-Nets, GANs, models including attention mechanisms such as transformers, diffusion models, etc. yield particularly good results.

A plausible design of an acquired aerial image can be obtained in different ways.

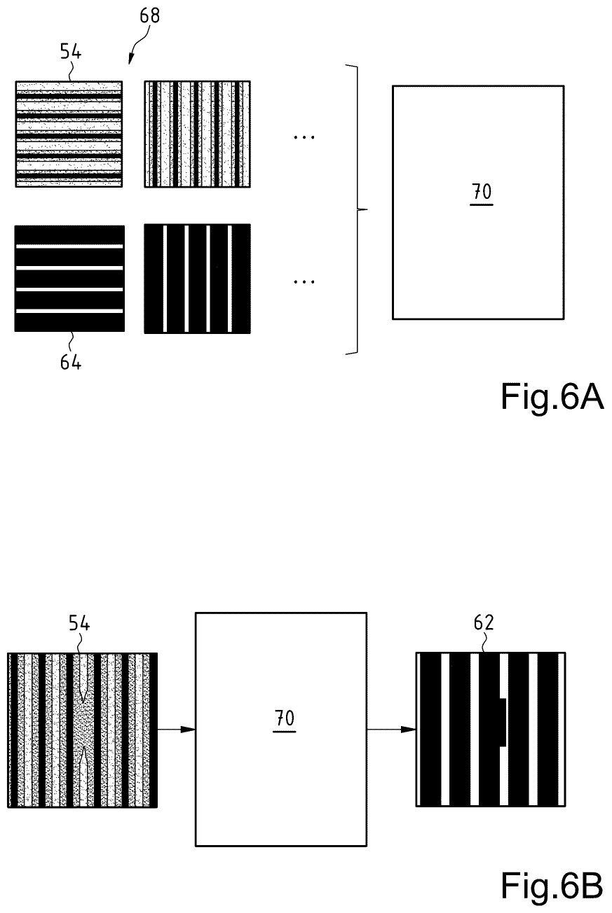

According to an example illustrated in FIGS. 6A and 6B, solving the optimization problem in step iii. comprises applying a machine learning model 70 to the acquired aerial image 54, wherein the machine learning model 70 is trained to map an acquired aerial image 54 to a plausible design 62 of the acquired aerial image 54, e.g., represented as a non-binary image. Thus, the acquired aerial image 54 is a plausible result of an aerial image simulation method applied to the plausible design 62. Solving the optimization problem here comprises applying a mathematical optimization method that comprises computing the output of a model, which was trained to optimize an objective function for a given input. The machine learning model 70 can be trained, as shown in FIG. 6A, using training images 68 comprising pairs of acquired aerial images 54 or simulated aerial images of photolithography masks 14 and corresponding designs.

The training images can, for example, comprise acquired aerial images 54 or simulated aerial images and their underlying designs 64. Preferably, at least some of the designs in the training images 68 contain uncommon structures. Uncommon structures are structures that are usually not part of a design, e.g., defects, design deviations that do not necessarily classify as defect such as small variations in design structures, e.g., thickness variations of structures, corner rounding, etc., or unexpected types of structures, e.g., in case only designs containing lines and spaces are contained in the training images, uncommon structures could comprise holes, crossings, assist features, complex polygons, etc.

Designs containing uncommon structures can be obtained by selecting an underlying design of an acquired or simulated aerial image that already includes uncommon structures, or by artificially introducing uncommon structures in a design. Aerial images corresponding to modified designs can be simulated from the modified designs using an aerial image simulation method. In this way, the uncommon structures such as defects can be controlled in their location, size, strength, type, frequency, etc. Thus, pairs of designs containing uncommon structures and corresponding aerial images can be obtained as training data 68 for the machine learning model 70.

The objective function optimized during training can comprise the deviation of the predicted plausible design 62 from the corresponding design. The objective function can also comprise the deviation of the acquired aerial images from simulated aerial images obtained by applying an aerial image simulation method to the corresponding designs. The machine learning model could use the underlying design 64 as additional input. In this case, the machine learning model could be trained using aerial images and perturbed underlying designs as input and the underlying designs without perturbation as output. The perturbations could model, e.g., line edge roughness or localized defects.

The machine learning model can comprise a neural network, in particular a deep neural network, e.g., a CNN or U-Net. The neural network can comprise one or more attention mechanisms that allow for learning connections between different regions of an acquired aerial image 54, thereby improving the results. The machine learning model can also comprise a random forest, a support vector machine, a decision tree, a clustering method, etc.

During inference, as shown in FIG. 6B, the machine learning model 70 directly maps an acquired aerial image 54 to a plausible design 62 of the acquired aerial image 54. As this only requires a single forward pass, this mapping can be carried out very quickly. By implementing the machine learning model 70 using, for example, graphics processing units (GPUs) or tensor processing units (TPUs) that allow for parallelization, the runtime during learning and inference can be strongly reduced.

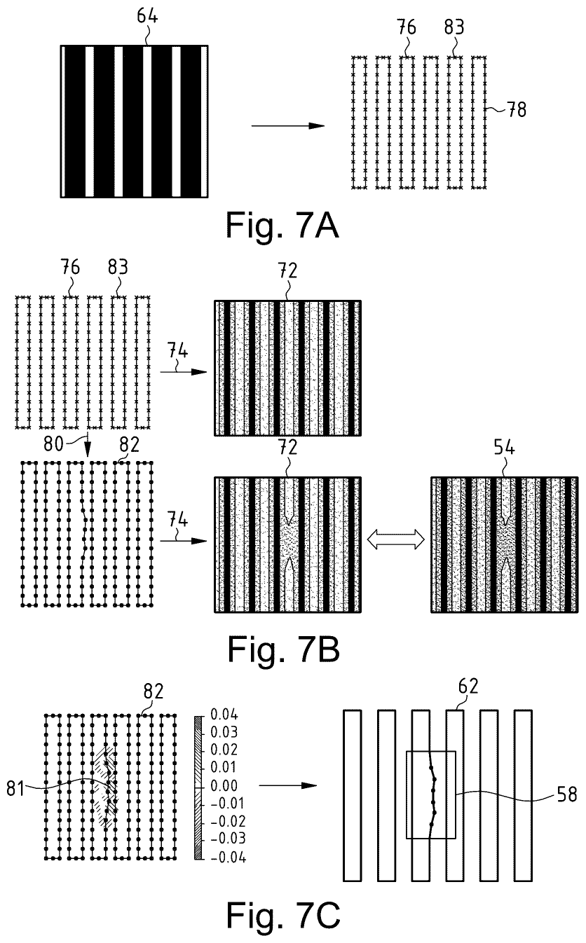

According to an example illustrated in FIGS. 7A to 7C, solving the optimization problem in step iii. comprises minimizing the deviation of the acquired aerial image 54 from a simulated aerial image 72, wherein the simulated aerial image 72 is obtained by applying an aerial image simulation method 74 to a design, in particular, to a modification of the underlying design 64.

According to an aspect, a parametric representation 76 of the underlying design 64, which is illustrated in FIG. 7A, is optimized by the optimization problem. The parametric representation 76 of the underlying design 64 can be modified until the optimization problem is solved. The solution of the optimization problem then corresponds to the plausible design 62. The parametric representation 76 can, for example, describe structure boundaries of the underlying design 64, e.g., a parametric representation 76 can comprise lines, edges, contours or geometric shapes such as polygons, circles, ellipses, etc. These parametric representations 76 can, for example, contain the locations of control points that are optimized. In an example, as shown in FIG. 7A, the parametric representation 76 comprises contours 78 represented by graphs containing nodes and edges. The contours, or the nodes and edges, can be derived, for example, from an underlying CAD design. The location of the nodes can be optimized by solving the optimization problem. Contours can also be represented by analytical functions describing the curve. The corresponding optimization problem could comprise an Active Contour or Snake objective function term to align the contours of the parametric representation 76 to the contours in the acquired aerial image 54.

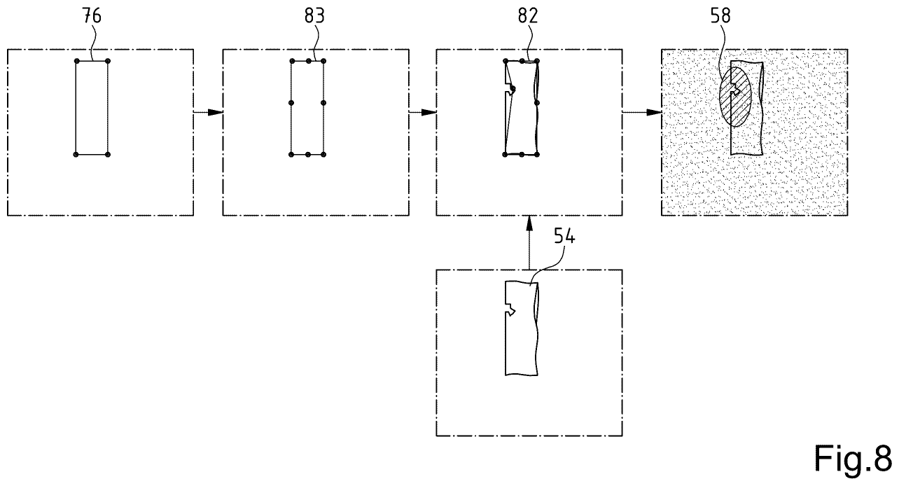

The parameters of the parametric representation 76 of the underlying design 64 are modified in the optimization problem as illustrated in FIG. 7B. An initial parametric representation is a parametric representation 76 that corresponds to the underlying design 64. This initial parametric representation 77 is optimized 80, yielding an optimized parametric representation 82 in order to minimize the deviation of the acquired aerial image 54 from a simulated aerial image 72 of the optimized parametric representation 82. The optimized parametric representation 82 is a parametric representation 76. During an iterative optimization, a simulated aerial image 72 is obtained from a modified parametric representation of the underlying design using an aerial image simulation method 74. The optimized parametric representation 82 then corresponds to a plausible design 62 of the acquired aerial image 54. The parametric representations 76 (including the initial parametric representation 77 and the optimized parametric representation 82) are, in this case, over-parameterized parametric representations 83, as more parameters than necessary are used to represent the design (as will be explained with respect to FIG. 8).

Depending on the deviation 81 of the optimized parametric representation 82 (corresponding to the plausible design 62) from the initial parametric representation 77 (corresponding to the underlying design 64) defects 58 can be detected. Metrics can be formulated to measure this deviation 81, e.g., the distance of a node in the initial parametric representation 77 from the corresponding shifted node in the optimized parametric representation 82 as indicated in FIG. 7C, or differences in size, length, area, etc. To detect defects, thresholds can be defined, e.g., by deriving confidence intervals from statistics. Alternatively, q-values of statistics can be used. Alternatively, machine learning models can be used to discriminate between defects and non-defects.

In an example, the optimization problem comprises parameters that describe a deviation 81 from the underlying design. Thus, only the deviation 81 of the parameters is optimized by solving the optimization problem, e.g., a shift of nodes, edges or contours, a contour length modification, an area modification, a size modification of some line or structure, etc. The optimization problem can impose a sparsity constraint on these parameters that describe a deviation 81 of the underlying design. In this way, the solution of the optimization problem, i.e., the plausible design 62, tends to only contain few deviations 81 of the parameters, e.g., only local modifications of points, nodes or edges as, for example, shown in FIG. 7C.

According to an aspect of the first embodiment illustrated in FIG. 8, the parametric representation 76 of the underlying design 64 is adapted, e.g., it is made more flexible to allow for modifications by use of over-parameterization. The parametric representation 76 of the underlying design 64 is over-parameterized. To this end, the contours can, for example, be subsampled to place additional nodes along the contours that can be shifted during optimization. Over-parametrization can increase the computation time, but at the same time the accuracy of the plausible design. FIG. 8 shows a parametric representation 76 that is derived from a CAD design by placing nodes at the corner points of the structures and connecting these by contour edges. To increase the flexibility of the parametric representation 76, further nodes are added along the contour edges yielding an over-parameterized parametric representation 83. DeepSnake-like approaches as, for example, described in the conference article “Peng, Sida, et al. “Deep snake for real-time instance segmentation.” Proceedings of the IEEE/CVF conference on computer vision and pattern recognition. 2020,” can, for example, be used to over-parameterize parametric representations 76. The over-parametrized parametric representation 83 is optimized to fit the acquired aerial image 54 by solving the optimization problem, thereby yielding an optimized parametric representation 82, the plausible design 62. From the deviation of the parametric representation 76 of the underlying design 64 from the optimized parametric representation 82 (the plausible design 62), defects 58 can be detected. In particular, defects 58 can be detected from the deviation of the optimized parametric representation 82 (the plausible design 62) from the over-parameterized parametric representation 83 or from the initial parametric representation 77. The parametric representations 76 including the initial parametric representation 77 and the optimized parametric representation 82 in FIG. 7 are also over-parametrized.

There are various aerial image simulation methods 74 that can be used for obtaining a simulated aerial image from the plausible design. An aerial image simulation method mathematically computes an aerial image from a design of a photolithography mask by simulating the application of an optical system, in particular an inspection system, a mask qualification system, a photolithography system or a metrology systems, to a photolithography mask corresponding to the design.

In a preferred example, the aerial image simulation method comprises the use of a physical model for generating an aerial image from the plausible design. This leads to accurate results but is often time consuming. Among these methods, there are rigorous simulation methods such as finite difference time domain (FDTD) or rigorous coupled wave analysis (RCWA) that are known to a person skilled in the art. Since they require long computation times, fast approximations such as the thin element approximation (TEA) can be used. The thin element approximation (TEA) assumes that the thickness of the structures on the photolithography mask is very small compared to the wavelength, and that the widths of the structures on the photolithography mask are very large compared to the wavelength. However, as photolithographic processes use radiation of shorter and shorter wavelengths, and the structures on the patterning device become smaller and smaller and grow into the vertical dimension, these assumptions do not hold anymore, and mask 3D effects must be taken into account. Therefore, the results of the TEA method are less accurate but much faster to obtain than rigorous simulation results.

To obtain fast and accurate results, simulation methods that are based on physical models but still do not rely on the thin mask assumption can be used.

According to an example, a not quite rigorous (NQR) aerial image simulation method can be used to simulate an aerial image from a design, in particular from the plausible design, obtained by an optical system. This method simulates an aerial image from the design under illumination of the corresponding photolithography mask by incident electromagnetic waves in the optical system accurately and quickly. For simulating the interaction of electromagnetic waves with a photolithography mask the propagation of the electromagnetic waves within the different layers of the photolithography mask comprising different materials with different refractive indices has to be taken into account.

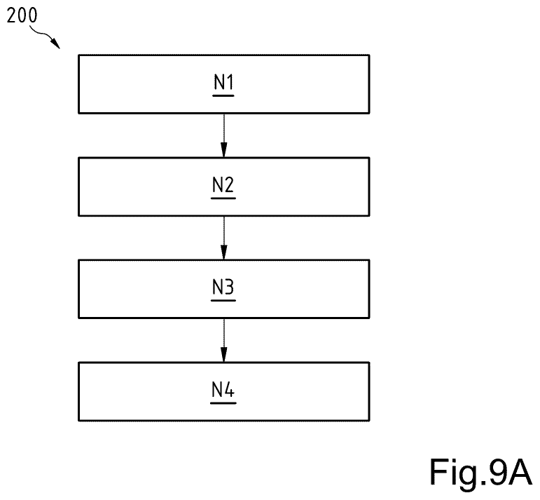

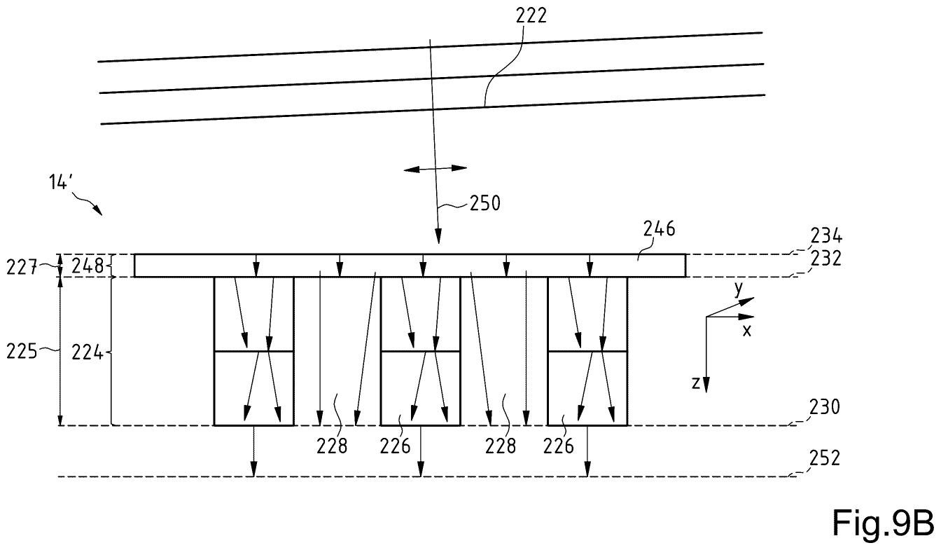

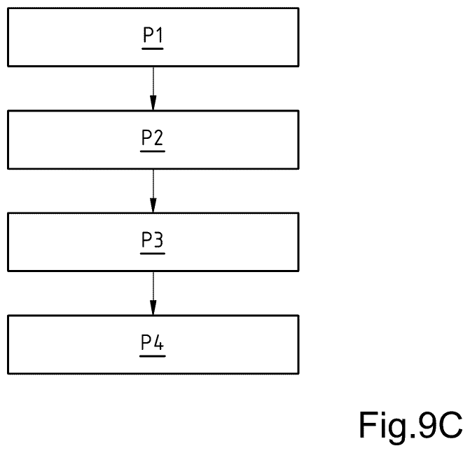

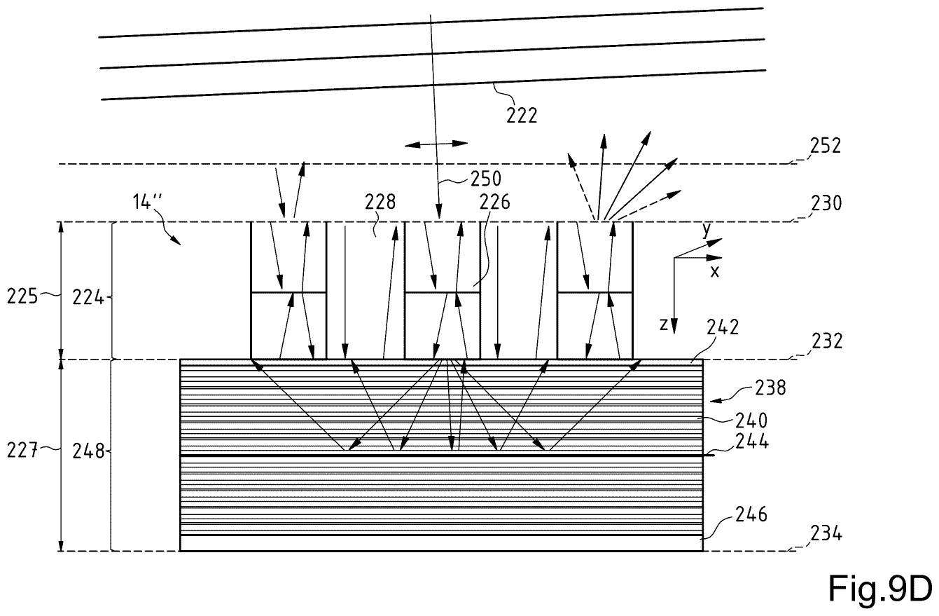

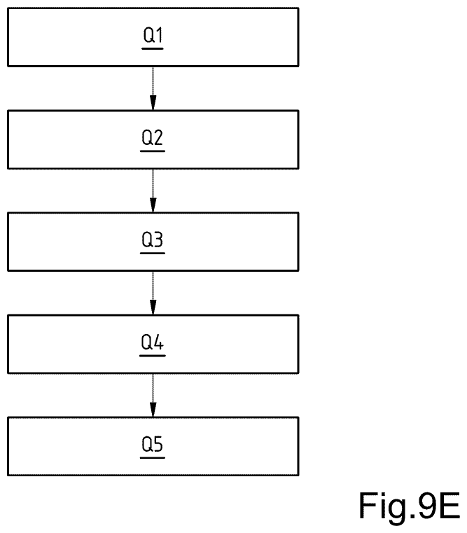

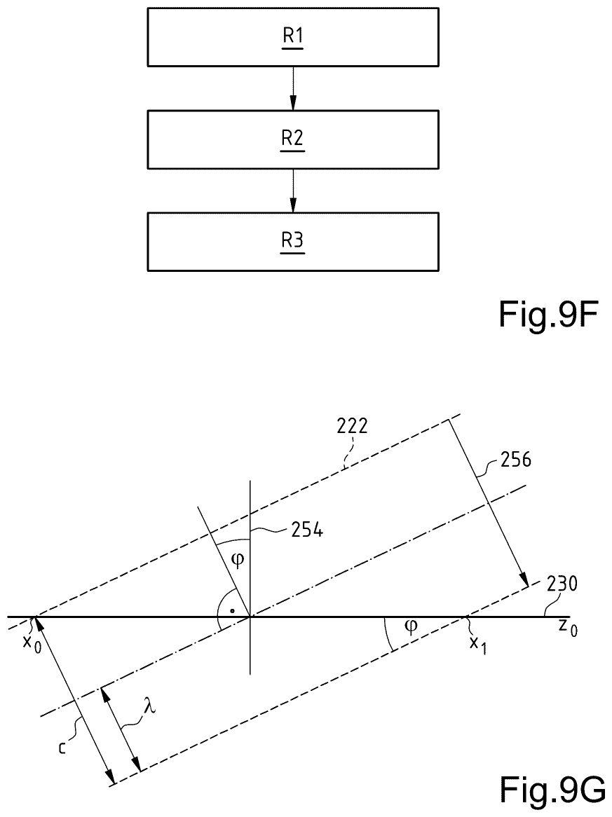

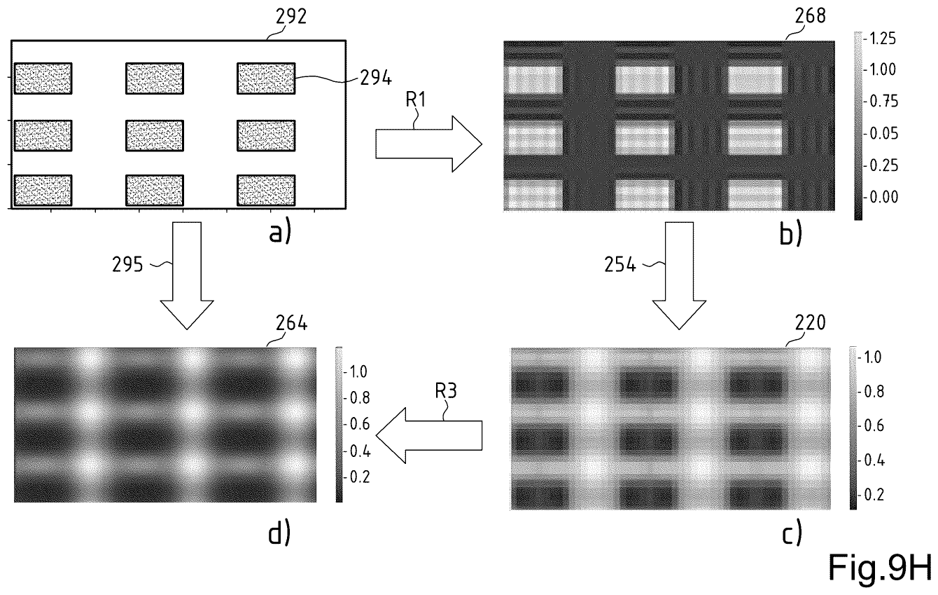

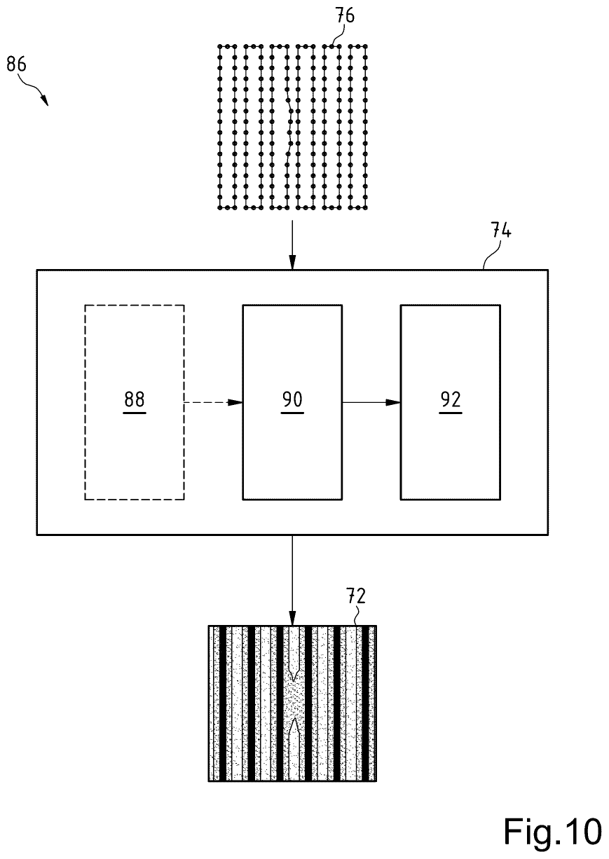

The not quite rigorous aerial image simulation method 200 for generating an aerial image of a design under illumination of a corresponding photolithography mask by incident electromagnetic waves by emulating the application of an optical system, in particular the mask inspection system, the optical mask qualification system or the specific photolithography system, to the photolithography mask is illustrated in FIG. 9A and comprises: a) approximately simulating the propagation of the incident electromagnetic waves within a first section of the photolithography mask that comprises multiple structures in a step N1; b) simulating the propagation of the simulated electromagnetic waves from step a) within a second section of the photolithography mask analytically or numerically in a step N2; c) simulating a representation of an electromagnetic near field of the photolithography mask by propagating the simulated electromagnetic waves from step b) to a near field plane in a step N3; and d) generating an aerial image of the photolithography mask by applying a simulation of an imaging process of the optical system to the representation of the electromagnetic near field in a step N4.

The not quite rigorous method 200 for generating an aerial image can be applied to transmission-based photolithography masks 14′ as illustrated in FIG. 9B and reflection-based photolithography masks 14″ as illustrated in FIG. 9D.

An electromagnetic near field indicates the distribution of the electromagnetic waves 222 in a near field plane 252. The near field plane 252 can be located next to a structure plane 230 of the photolithography mask 14. Preferably, the near field plane 252 is parallel to the structure plane 230 or the base plane 234 of the photolithography mask 14. The near field plane 252 can, in general, be located anywhere between the structure plane 230 and the wafer plane 18, for example, at a distance between 0 and 1000 nm from the structure plane 230, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane 252 and the structure plane 230 are identical.

According to an embodiment, the photolithography mask 14 comprises a mask carrier 248 and a grating 224, the grating 224 comprises absorber structures 226 and non-absorber structures 228 forming a design 292 on at least a portion of the mask carrier 248. The photolithography mask 14 comprises a first section 225 extending between a structure plane 230 and a boundary plane 232 of the photolithography mask 14 and a second section 227 extending between the boundary plane 232 and a base plane 234 of the photolithography mask 14. The first section 225 comprises the grating 224, and the second section 227 comprises the mask carrier 248.

FIG. 9B illustrates the propagation of incoming electromagnetic waves 222 through a transmission-based photolithography mask 14′, e.g., a DUV photolithography mask. The photolithography mask 14′ comprises a first section 225 and a second section 227. The first section 225 contains a grating 224, and the second section 227 contains a mask carrier 248. The grating 224 is formed by a combination of absorber structures 226 and non-absorber structures 228. The absorber structures 226 are made of one or more materials which absorb electromagnetic waves 222, e.g. titanium nitride or tantalum nitride, etc. The non-absorber structures 228 are made of one or more materials which absorb electromagnetic waves 222 to a lower degree than the absorber material. For example, the non-absorber structures 228 can comprise vacuum. Thus, the grating 224 is an inhomogeneous medium. The absorber structures 226 and the non-absorber structures 228 are deposited on a mask carrier 248. The mask carrier 248 can comprise a substrate layer 246. The mask carrier 248 in the photolithography mask 14′ is delimited by a boundary plane 232 and a base plane 234 which is preferably parallel to the boundary plane 232. The boundary plane 232 is a surface plane of the mask carrier 248. The base plane 234 is a boundary plane through which the electromagnetic waves 222 enter the grating 224. The incoming electromagnetic wave 222 impinges on the base plane 234. The base plane 234 forms an interface between the mask carrier 248 and the outside of the photolithography mask 14′ through which the electromagnetic waves 222 propagate. The absorber structures 226 in the grating 224 of the photolithography mask 14′ are delimited by the boundary plane 232 and a structure plane 230. The structure plane 230 is a boundary plane which contains the portion of the surface of the absorber structures 226, which is facing away from the boundary plane 232. Preferably, the structure plane 230 is parallel to the boundary plane 232. The first section 225 of the photolithography mask 14′ extends between the structure plane 230 and the boundary plane 232 and is delimited by these planes. The second section 227 of the photolithography mask 14′ extends between the boundary plane 232 and the base plane 234 and is delimited by the boundary plane 232 and the base plane 234.

For transmission-based photolithography masks 14′, according to an example, the simulated electromagnetic waves 222 are incident on the base plane 234, propagated within the second section 227 of the photolithography mask 14′ from the base plane 234 to the boundary plane 232, and within the first section 225 of the photolithography mask 14 from the boundary plane 232 to the structure plane 230.

FIG. 9C shows a flowchart of the not quite rigorous method for generating an aerial image in case of a transmission-based photolithography mask 14′ as shown in FIG. 9B. The simulated electromagnetic waves 222 are incident on the photolithography mask, e.g., on the base plane 234, propagated within the second section 227 of the photolithography mask, e.g., from the base plane 234 to the boundary plane 232, in a step P1, and within the first section 225 of the photolithography mask 14′, e.g., from the boundary plane 232 to the structure plane 230, in a step P2. Then a representation of the electromagnetic near field of the photolithography mask 14′ in a near field plane 252 is obtained in a step P3. Finally, an aerial image is generated from the representation of the near field by applying a simulation of an imaging process of an optical system to the representation of the electromagnetic near field in a step P4.

For reflection-based photolithography masks 14″, according to an example illustrated in FIG. 9D, the mask carrier 248 comprises a multilayer 238 in the form of a stack of optical thin films 240 for reflecting the electromagnetic waves 222, and the simulated electromagnetic waves 222 are incident on the structure plane 230, propagated within the first section 225 of the photolithography mask 14″ from the structure plane 230 to the boundary plane 232, reflected within the multilayer 238 in the second section 227 of the photolithography mask 14″ and propagated within the first section 225 of the photolithography mask 14″ from the boundary plane 232 to the structure plane 230. In this way, the not quite rigorous method 200 for generating an aerial image can be applied to reflection-based photolithography masks 14″, e.g., EUV photolithography masks.

FIG. 9D illustrates the propagation of incoming electromagnetic waves 222 through a reflection-based photolithography mask 14″, e.g., an EUV photolithography mask. The photolithography mask 14″ comprises a first section 225 and a second section 227. The first section 225 contains a grating 224, and the second section 227 contains a mask carrier 248. The grating 224 contains absorber structures 226 and non-absorber structures 228 forming a design on at least a portion of the mask carrier 248 to be printed onto a wafer. The absorber structures 226 are made of one or more materials which absorb electromagnetic waves 222, e.g., titanium nitride or tantalum nitride, etc. The non-absorber structures 228 are made of one or more materials which absorb electromagnetic waves 222 to a lower degree than the absorber material. For example, the non-absorber structures 228 can comprise vacuum. Thus, the absorber structures 226 and the non-absorber structures 228 form an inhomogeneous medium. The absorber structures 226 and the non-absorber structures 228 are deposited on a mask carrier 248. The mask carrier 248 comprises a multilayer 238 in the form of a stack of optical thin films 240 for reflecting the electromagnetic waves 222. The mask carrier 248 can comprise a capping layer 242 and/or a substrate layer 246. The reflection of the electromagnetic waves 222 by the stack of optical thin films 240 corresponds to a reflection of the electromagnetic waves 222 at the effective mirror plane 244. The mask carrier 248 in the photolithography mask 14″ is delimited by a boundary plane 232 and a base plane 234 which is preferably parallel to the boundary plane 232. The boundary plane 232 is a surface plane of the mask carrier 248. The absorber structures 228 in the grating 224 of the photolithography mask 14″ are delimited by the boundary plane 232 and a structure plane 230. The structure plane 230 is a boundary plane which contains the portion of the surface of the absorber structures 226, which is facing away from the boundary plane 232. Preferably, the structure plane 230 is parallel to the boundary plane 232.

The structure plane 230 is a boundary plane through which the electromagnetic waves 222 enter the first section 225, e.g., the grating 224. The incoming electromagnetic waves 222 impinge on the structure plane 230. The structure plane 230 is forming an interface between the photolithography mask 14″ and the outside of the photolithography mask 14″ through which the electromagnetic waves 222 propagate. The first section 225 of the photolithography mask 14″ extends between the structure plane 230 and the boundary plane 232 and is delimited by these planes. The second section 227 of the photolithography mask 14″ extends between the boundary plane 232 and the base plane 234 and is delimited by the boundary plane 232 and the base plane 234.

FIG. 9E shows a flowchart of an example of the not quite rigorous method 200 for generating an aerial image of a design of a photolithography mask 14 in case of a reflection-based photolithography mask 14″ as shown in FIG. 9D. The mask carrier 248 comprises a multilayer 238 in the form of a stack of optical thin films 240 for reflecting the electromagnetic waves 222, and the simulated electromagnetic waves 222 are incident on the photolithography mask, e.g., on the structure plane 230, propagated within the first section 225 of the photolithography mask 14″, e.g., from the structure plane 230 to the boundary plane 232, in a step Q1, reflected within the multilayer 238 in the second section 227 of the photolithography mask 14″ in a step Q2 and propagated within the first section 225 of the photolithography mask 14″, e.g., from the boundary plane 232 to the structure plane 230, in a step Q3. Then a representation of the electromagnetic near field of the photolithography mask 14″ in a near field plane 252 is obtained in a step Q4. Finally, an aerial image is generated from the representation of the near field by applying a simulation of an imaging process of an optical system to the representation of the electromagnetic near field in a step Q5.

Instead of solving the Maxwell equations directly in the first section 225, different approximations can be used to reduce the computation time of the method. According to an example, the propagation of the incident electromagnetic waves within the first section 225 of the photolithography mask 14 in step a) is approximately simulated using a Helmholtz equation, in particular a forward Helmholtz equation.

In the photolithography setting, the following assumptions can be made: 1) the refractive index is similar for the different materials of the photolithography mask 14, e.g., the refractive index of the structures 226, in particular the absorber structures, is close to the refractive index outside the structures 226, in particular the non-absorber structures, e.g., vacuum. 2) The refractive index distribution in the first section 225 is piecewise constant without requiring a transition to be modeled. 3) The main propagation direction 250 of the incoming electromagnetic waves 222 is near vertical with respect to a main surface of the photolithography mask, in particular to the base plane 234. These assumptions allow for a simplified approximation of the propagation of the electromagnetic waves 222 within the first section 225.

Based on the time-harmonic Maxwell equations, the following equation can be derived for the electric field E of an electromagnetic wave 222:

$$Δ E ( r , ω ) + \frac{{ω}^{2}}{{c}^{2}} ϵ ( r , ω ) E ( r , ω ) = - ∇ \cdot ( \frac{∇ ϵ ( r , ω )}{ϵ ( r , ω )} \cdot E ( r , ω ) ) , \qquad ( 1 )$$

where ω is the angular frequency, c the speed of light and ϵ(r, ω) the dielectric function characterizing the specific material. These relations are connected to the refractive index n(r, ω) of a material via ϵ(r, ω)=n(r, ω)². The right-hand side couples the electric field components, which makes it hard to find solutions to this equation. Therefore, the right-hand side is preferably neglected. The neglection of the right-hand side remains valid if the following two assumptions are fulfilled: the considered optical system does not show a distinctive response depending upon the incident polarization, and there is no cross coupling between individual polarization components. For the lithography setting at short wavelengths, e.g., for DUV or EUV photolithography masks, there are two reasons for neglecting polarization and phononic effects, so these assumptions are valid. Firstly, the contrasts in the refractive index are low with respect to the different materials within the structures 226 and outside the structures in the first section 225. Secondly, the height a of the structures 226 is larger than the wavelengin λ,

$$i . e . \frac{a}{λ} \geq 2 .$$

Therefore, the right-hand side of equation (1) can be neglected resulting in a Helmholtz equation

$$Δ E ( r , ω ) + \frac{{ω}^{2}}{{c}^{2}} ϵ ( r , ω ) E ( r , ω ) = 0$$

The Helmholtz equation can be simplified further. Using the following relations concerning the magnitude of the wave number |k|

$$\vert k \vert = \sqrt{{k}_{x}^{2} + {k}_{y}^{2} + {k}_{z}^{2}} = \frac{ω}{c} n ( r , ω )$$

and its connection to the wavelength λ

$$\vert k \vert = {k}_{0} n ( r , ω ) = \frac{2 π}{{λ}_{0}} n ( r , ω ) ,$$

where k₀ and λ₀ are respectively the wave vector and wavelength in vacuum, the Helmholtz equation can be rewritten as

$$Δ E ( r , ω ) + {k}_{o}^{2} {n}^{2} ( r , ω ) E ( r , ω ) = 0 .$$

This equation can be rewritten using the transverse Helmholtz operator as follows:

$$( {δ}_{z}^{2} + {ℋ}_{𝒯} ) {E}_{x , y} = 0 ,$$

$$where$$

$${ℋ}_{𝒯} = {δ}_{x}^{2} + {δ}_{y}^{2} + {k}_{0}^{2} {n}^{2} ( x , y , z ) .$$

This equation can be rewritten as

$$( i \sqrt{{ℋ}_{𝒯}} + {δ}_{z} ) ( i \sqrt{{ℋ}_{𝒯}} - {δ}_{z} ) {E}_{x , y} = 0 .$$

Here, the square root Helmholtz operator is introduced, being formally defined in terms of a power-series. Moreover, it is assumed that the commutator δz [symbol] can be neglected, which physically implies that back reflections within the inhomogeneous medium are ignored. Then, the forward Helmholtz equation is identified as

$${δ}_{z} {E}_{x , y} = i \sqrt{{ℋ}_{𝒯}} {E}_{x , y} .$$

The ordinary partial differential equation can be solved using multiplication with an integrating factor:

$${E}_{x , y} ( x , y , {z}_{0} + z ) = {exp}^{iz \sqrt{{ℋ}_{𝒯}}} {E}_{x , y} ( x , y , {z}_{0} ) .$$

The exponential operator can be approximated by an integral operator as shown in the appendix A of the PhD thesis “Efficient wave-optical simulations for the modeling of micro-optical elements” by Soeren Schmidt at the University of Jena. Reference is hereby made in full to the aforementioned PhD thesis, and its disclosure content is incorporated herein by reference in the description of this invention. The approximation by the integral operator yields:

$$E ( x , y , {z}_{0} + Δ z ) = \frac{1}{2 π} \int \tilde{E} ( x , y , {z}_{0} ) {e}^{- {ik}_{z} ( {k}_{x} , {k}_{y} , x , y ) Δ z} {e}^{i ( {k}_{x} , x + {k}_{y} y )} {dk}_{x} {dk}_{y} ,$$

$$\begin{matrix}\tilde{E} ( x , y , {z}_{0} ) & = \frac{1}{2 π} \int E ( x , y , {z}_{0} ) {e}^{- i ( {k}_{x} x + {k}_{y} y )} dx dy \\ & = ℱ \{ E ( x , y , {z}_{0} ) \}\end{matrix}$$

$${k}_{z} = \sqrt{{k}_{0}^{2} {n}^{2} - {k}_{x}^{2} - {k}_{y}^{2}} .$$

This approach is referred to as the angular spectrum of plane wave decomposition (ASPW) as shown in equation 1.8 of the aforementioned PHD thesis “Efficient wave-optical simulations for the modeling of micro-optical elements.” It assumes that the electromagnetic waves are propagated within a homogeneous medium with refractive index n. However, this does not hold for the first section 225 of the photolithography mask 14 comprising structures 226 and non-structures 228.

Therefore, an extension of the ASPW to inhomogeneous media is required to describe the propagation of electromagnetic waves 222 within the first section 225 of the photolithography mask 14.

In order to account for inhomogeneous media, the propagation constant in a subsequent plane z to a given plane z₀ is computed according to the refractive index distribution as described in section 1.4 of the aforementioned PhD thesis

$${k}_{z} ( x , y , {k}_{x} , {k}_{y} ) = \sqrt{{k}_{0}^{2} n {( x , y , {z}_{0} )}^{2} - {k}_{x}^{2} - {k}_{y}^{2}} .$$

Therefore, according to an example, the forward Helmholtz equation can be solved using a wave propagation method. The wave propagation method is a generalization of the ASPW to inhomogeneous media and describes a wave propagation step in a plane z₀ along the z-direction perpendicular to the base plane by

$$E ( x , y , {z}_{0} + Δ z ) = \frac{1}{2 π} \int ℱ \{ E ( x , y , {z}_{0} ) \} {e}^{{ik}_{z} ( x , y , {k}_{x} , {k}_{y} ) Δ z} {e}^{i ( {k}_{x} x + {k}_{y} y )} {dk}_{x} {dk}_{y} , \qquad ( 2 )$$

where E denotes the electric field component of the electromagnetic field and (kₓ, k_{y}, k_{z})^{T} the wave vector, which locally obeys the dispersion relation

$${k}_{z} ( x , y , {k}_{x} , {k}_{y} ) = \sqrt{{k}_{0}^{2} n {( x , y , {z}_{0} )}^{2} - {k}_{x}^{2} - {k}_{y}^{2}} , \qquad ( 3 )$$

where

$${k}_{0} = \frac{2 π}{{λ}_{0}}$$

denotes the wavenumber of light with a wavelength λ₀ in vacuum, n(x, y, z) the refractive index distribution and [symbol] the spatial Fourier Transform. The magnitude of the wave vector k is inversely proportional to the wavelength λ, and the direction of the wave vector is perpendicular to the wave front. By using this wave propagation method, the propagation of the electromagnetic waves within an inhomogeneous medium can be modeled leading to an accurate approximation of the propagation of the electromagnetic waves within the first section of the photolithography mask.

In an embodiment, the first section 225 of the photolithography mask 14 comprises structures 226 and non-structures 228 forming an inhomogeneous medium, e.g., the grating 224 comprises absorber structures and non-absorber structures. The simulation of the propagation of the electromagnetic waves 222 within the first section 225 takes into account this inhomogeneity of the material within the first section 225. At the same time, several simplifying assumptions can be exploited in the photolithography setting. In addition, the simulation of the propagation of the electromagnetic waves 222 within the second section 227 is computed analytically or numerically. In this way, an accurate and fast simulation of the propagation of the electromagnetic waves 222 within the photolithography mask 14 is obtained.

Alternatively, the forward Helmholtz equation can be solved using a beam propagation method. The beam propagation method is described, for example, in chapter 1.3 of the above-mentioned PhD thesis “Efficient wave-optical simulations for the modeling of micro-optical elements” by Soeren Schmidt.

In an example, the propagation of the incident electromagnetic waves within the first section of the photolithography mask in step a) is approximately simulated using a machine learning model. The machine learning model can, for example, comprise a neural network, e.g., a deep learning model. For example, the machine learning model can comprise a U-Net or a neural network with at least one attention mechanism, e.g., a Transformer machine learning model. The machine learning model can use a model of the photolithography mask, e.g., a design pattern, as input and map the input to an electromagnetic field as output. The machine learning model can be trained using training data obtained, e.g., from simulations described above. By using a machine learning model, the computation time can be strongly reduced, as after training a single and fast forward pass is sufficient to compute the propagation of the incident electromagnetic waves.

Due to the dependence of the dispersion relation in (3) on the spatial variables (x,y) the wave propagation method in (2) cannot be implemented using Fast Fourier Transforms (FFT). In order to use FFTs and reduce the computation time the wave propagation method in (2) can be reformulated using characteristic functions.

In an example, the first section 225 of the photolithography mask 14 is decomposed into different materials by defining a characteristic function for each material that indicates the presence of the material within different locations in the first section 225 of the photolithography mask 14, wherein at least one characteristic function is non-binary.

The first section 225 of the photolithography mask 14 can be decomposed into a finite number M of pairwise disjoint and homogeneous subregions with refractive index nₘ. Then, the refractive index distribution n (x, y, z₀) within a given layer z₀ can be rewritten using characteristic functions. A characteristic function

$${I}_{m}^{{z}_{0}} : X \times Y \to 𝒟$$

for a material m is a mapping from a spatial domain X×Y⊆ [symbol] × [symbol] to a value range [symbol] , which represents the presence of the material m for each location (x,y) of the spatial domain. For example,

$${I}_{m}^{{z}_{0}} ( x , y ) = \{ \begin{matrix}1 , & n ( x , y , {z}_{0} ) = {n}_{m} \\ 0 , & n ( x , y , {z}_{0} ) \neq {n}_{m}\end{matrix}$$

indicates a binary characteristic function with a value range [symbol] ={0,1}, where nm indicates the refractive index of material m. [symbol] can, for example, be a subset of the real numbers [symbol] ( [symbol] ⊆ [symbol] ) or of the complex numbers [symbol] ( [symbol] ⊆ [symbol] ).

FIG. 9F shows a flowchart of the not quite rigorous method for generating an aerial image according to an example, comprising an additional characteristic function step R1 followed by simulating a representation of an electromagnetic near field in a step R2 and by applying a simulation of an imaging process of an optical system to the representation of the resulting electromagnetic near field in a step R3.

The step R1 comprises: identifying a number M of materials of the structures 226 in the first section 225 forming the design 292 of the photolithography mask 14; defining a characteristic function

$${I}_{m}^{{z}_{0}} : X \times Y \to 𝒟$$

for each material m∈{1, . . . , M} indicating the presence of the material for locations (x,y) of the photolithography mask 14 within a subset X×Y⊆ [symbol] × [symbol] of an x/y-plane at z=z₀, wherein the x/y-plane is orthogonal to the z-direction, which is perpendicular to the base plane 34; simulating the propagation of the electromagnetic waves 222 as a weighted sum over a propagation step within each of the identified materials:

$$E ( x , y , {z}_{0} + Δ z ) = {\sum }_{m = 1}^{M} {I}_{m}^{{z}_{0}} ( x , y ) {ℱ}^{- 1} \{ {e}^{{ik}_{z}^{m} ( {k}_{x} , {k}_{y} ) Δ z} ℱ \{ E ( x , y , {z}_{0} ) \} \} , \qquad ( 4 )$$

where [symbol] ⁻¹ indicates the inverse Fourier Transform. The use of characteristic functions allows for an FFT based implementation of the wave propagation method in (2), thus saving computation time. The integrator in (4) converges linearly with the step size.

However, the discretization of the commonly used binary characteristic functions is problematic. Since binary characteristic functions are discontinuous, the Shannon-Nyquist theorem requires a very high sampling frequency (at least twice the maximum frequency of the signal) and, thus, a very high resolution of the sampling grid. In particular, if the edges of the structures 226 do not align with the sampling grid, the sampling is inaccurate. In addition, the resolution of the sampling grid depends on the size of the smallest feature. The high resolution of the sampling grid in turn leads to high computation times for generating the aerial image.

Therefore, according to an aspect of the example the characteristic functions are band-limited. A band-limited characteristic function is a characteristic function for which a finite frequency ω₀ exists such that

$$ℱ ( ω ) = 0 for \vert ω \vert > {ω}_{0} .$$

According to the Shannon-Nyquist theorem, on the one hand the required sampling frequency of the discretization of a band-limited characteristic function depends on its maximum frequency. On the other hand, a given sampling frequency of a discretization of a band-limited characteristic function directly implies its maximum frequency.

By using band-limited characteristic functions, the maximum frequency of the characteristic functions can be limited. In this way, according to the Shannon-Nyquist theorem, the required sampling frequency is reduced, so a sampling grid of lower resolution can be used for discretizing the characteristic functions (than in case of binary characteristic functions). In this way, the required computation times for generating the aerial image can be reduced. In addition, the resolution of the sampling grid is independent from the feature size of the features in the design of the photolithography mask. In contrast, for binary characteristic functions, the sampling grid resolution depends on the smallest feature of the design of the photolithography mask.

A justification of using discretized band-limited characteristic functions is given in the following: Assuming that the electromagnetic field E only contains energy at long wavelengths in the x/y-plane perpendicular to the base plane 234 of the photolithography mask 14, a linear space invariant low-pass filter P has no effect when applied to the electromagnetic field E, that is:

$$P ( E ) \approx E .$$

Equivalently, P can be written as a convolution in time domain, and the above implies:

$$\begin{matrix}P ( E ) & = \int p ( {t}^{′} ) E ( t - {t}^{′} ) {dt}^{′} \\ & \approx \int p ( {t}^{′} ) E ( t ) {dt}^{′} \\ & = E ( t ) \int p ( {t}^{′} ) {dt}^{′} \\ & = E .\end{matrix}$$

If the filter P is applied to the product of E with a function O having energy at shorter wavelengths, it follows:

$$\begin{matrix}P ( E \cdot Θ ) & = \int p ( {t}^{′} ) E ( t - {t}^{′} ) Θ ( t - {t}^{′} ) {dt}^{′} \\ & \approx \int p ( {t}^{′} ) E ( t ) Θ ( t - {t}^{′} ) {dt}^{′} \\ & = E ( t ) \int p ( {t}^{′} ) Θ ( t - {t}^{′} ) {dt}^{′} \\ & = E \cdot P ( Θ ) .\end{matrix}$$

Thus, if a low pass filter is applied to the product of a slowly varying function E and a fastly varying function O, then the result is approximately the product of the slowly varying function E and the filtered fastly varying function P(Θ).

Applying this result to the propagator of the wave propagation method in (4)

$$P [ E ( {z}_{0} + Δ z ) ] = P ( {\sum }_{m = 1}^{M} {I}_{m}^{{z}_{0}} ( {x}_{x} y ) O [ E ( {z}_{0} ) ] ) ,$$

where O denotes the linear ASPW propagator

$$O [ E ( {z}_{0} ) ] = {ℱ}^{- 1} \{ {e}^{{ik}_{Z}^{m} ( {k}_{x} , {k}_{y} ) Δ z} ℱ \{ E ( {z}_{0} ) \} \} \qquad ( 5 )$$

and assuming that the electromagnetic field E(z₀) varies on a longer scale than the characteristic functions

$${I}_{m}^{{z}_{0}} ,$$

it follows:

$$P [ E ( {z}_{0} + Δ z ) ] \approx {\sum }_{m = 1}^{M} P ( {I}_{m}^{{z}_{0}} ) O [ E ( {z}_{0} ) ] .$$

Thus, the propagator for the low frequency part of the field E in the wave propagation method in (4) is obtained by applying the filter P to the characteristic functions.

By generalizing the concept of characteristic functions to non-binary characteristic functions sub-pixel design features can be resolved, and a speedup factor of about 100 can be achieved.

Apart from band-limited characteristic functions, it is also advantageous to use other non-binary characteristic functions to describe the presence of specific materials in different locations (x, y)∈X×Y of the photolithography mask 14 at z=z₀.

For example, it is advantageous to use continuous characteristic functions or complex valued characteristic functions. In this way, the material distribution within the photolithography mask can be described in a more flexible way leading to approximations of higher accuracy.

According to an aspect of the example, the value range [symbol] of at least one characteristic function comprises at least one value

$${I}_{m}^{{z}_{0}} ( x , y ) ∉ \{ 0 , 1 \} .$$

Thus, at least one characteristic function is not a binary characteristic function, since it maps to at least one non-binary value. In this way, different materials m can be present in the same location (x,y) allowing for a more flexible modeling of the refractive index distribution in the photolithography mask 14, thereby obtaining a more general description of the material distribution in the photolithography mask. By using characteristic functions having overlapping support the accuracy of the wave propagation method can be improved. The support of a real-valued function is the subset of the function domain containing the elements which are not mapped to zero. On the one hand, the presence of different materials in the same location of the photolithography mask can be used to model the distribution of materials in case that different materials are present in the same location. On the other hand, assuming the presence of different materials in the same location can be used as a mathematical means to improve the accuracy of the electromagnetic near field and aerial image even if this material distribution does not correspond to the true material distribution. In this way, more accurate electromagnetic near fields and aerial images can be computed.

According to an aspect of the example, the characteristic functions form an affine combination at each location in the first section of the photolithography mask. That means that at z=z₀:

$${\sum }_{m = 1}^{M} {I}_{m}^{{z}_{0}} ( x , y ) = 1 ∀ ( x , y ) ∈ X \times Y .$$

In particular, the characteristic functions can form a convex combination at each location of the photolithography mask at z=z₀. This constraint ensures that the amount of material present in each location of the domain of the characteristic functions is the same and amounts to 1. Thus, an accurate description of the material distribution within the photolithography mask 14 is obtained leading to an accurate approximation of the propagation of the electromagnetic waves 222 within the photolithography mask 14.

According to an aspect of the example, obtaining the characteristic functions comprises decomposing the design of the photolithography mask 14 into elements (e.g., using mathematical functions that describe the contours or area of the structures 226 such as polygons, Splines, curvilinear elements, etc.), representing the elements 294 by characteristic functions, in particular by binary characteristic functions, and applying a low pass filter to the characteristic functions. The elements 294 can, for example, be represented by characteristic functions taking on a non-zero value, for example 1, inside the element 94 and 0 outside the element 294. For example, each element 294 can be decomposed into one or more triangles, and the triangles can be represented by characteristic functions. The Fourier Transform of polygons can be obtained as described in appendix A of the PhD thesis “Photolithography Simulation by Heinrich Kirchauer at the Technical University of Wien.” Reference is hereby made in full to the aforementioned PhD thesis, and its disclosure content is incorporated herein by reference in the description of this invention. By applying a low pass filter to the characteristic functions band-limited characteristic functions 68 are obtained. Thus, the wave propagation method in (4) can be simulated using a coarse sampling grid as described above, thereby reducing the computation time.

In an example, a low pass filter is applied to the characteristic functions. In particular, applying a low pass filter to the characteristic functions can comprise applying a spatial analytical Fourier Transform to the characteristic functions followed by an inverse Fourier Transform. The analytical Fourier transform can be computed only for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a representation of the design of the photolithography mask by use of band-limited characteristic functions, which can be discretized using a sampling grid of a resolution much lower than for binary characteristic functions, thereby reducing the computation time.

According to an example, the analytical Fourier Transform used in the wave propagation method in equation (4) is approximated by a Fast Fourier Transform (FFT) and/or an analytical inverse Fourier Transform by a Fast Inverse Fourier Transform. In this way, the computation time is reduced.

The FFT implies periodic boundary conditions. However, due to the arbitrary angle of the incident electromagnetic waves, this assumption does not hold anymore. This inaccuracy is often ignored by approximation methods. Even if the mask design 292 is assumed to be periodic, the arbitrary illumination angle of the incident electromagnetic waves 222, e.g., with respect to the normal 254 of the structure plane 230, implies that the solution of equation (4) is only quasi periodic according to the Floquet Theorem, that means periodic with an additional phase shift α:

$$E ( x + n Δ x ) = E ( x ) {exp}^{in α} .$$

Therefore, according to an example, the wave propagation method approximates an analytical Fourier Transform by a Fast Fourier Transform, and the wave propagation method takes into account the angle ϕ of the incident electromagnetic waves 222, e.g., the angle with respect to the normal 254 of the structure plane 230, by assuming quasiperiodic boundary conditions in the propagator step in equation (4) at one or more pairs of opposite boundaries perpendicular to a base plane 234 of the photolithography mask 14, that is in the x/y-plane. By assuming quasiperiodic boundary conditions, the accuracy of the simulated electromagnetic near field is improved.

Let E(x, y, z₀) be quasi-periodic in the x and y coordinates. Then, according to the Floquet theorem, E can be rewritten as a part E′ that is periodic in x and y multiplied with a non-periodic phase shift α=(αₓ, α_{y}) as follows:

$$E ( x , y , {z}_{0} ) = {E}^{′} ( x , y , {z}_{0} ) {exp}^{i ( {α}_{x} x + {α}_{y} y )} .$$

Then the Fourier transform of the periodic part E′ can be written as

$$= F \{ {E}^{′} \} = \tilde{E} ( {k}_{x} - {α}_{x} , {k}_{y} - {α}_{y} , {z}_{0} ) .$$

It follows that

$$( {k}_{x} + {α}_{x} , {k}_{y} + {α}_{y} , {z}_{0} ) = \tilde{E} ( {k}_{x} , {k}_{y} , {z}_{0} ) .$$

Using

$$\tilde{E} ( {k}_{x} , {k}_{y} , {z}_{0} ) = ℱ \{ E ( x , y , {z}_{0} ) \} .$$

we obtain

$$\begin{matrix}E ( x , y , {z}_{0} + Δ z ) = {ℱ}^{- 1} \{ {exp}^{i {k}_{z} ( {k}_{x} , {k}_{y} ) Δ z} \tilde{E} ( {k}_{x} , {k}_{y} , {z}_{0} ) \} \\ = {ℱ}^{- 1} \{ {exp}^{i {k}_{z} ( {k}_{x} , {k}_{y} ) Δ z} \tilde{{E}^{′}} ( {k}_{x} + {α}_{x} , {k}_{y} + {α}_{y} , {z}_{0} ) \} \\ = {ℱ}^{- 1} \{ {exp}^{i {k}_{z} ( {k}_{x} - {α}_{x} , {k}_{y} - {α}_{y} ) Δ z} \tilde{E} ( {k}_{x} , {k}_{y} , {z}_{0} ) \} {exp}^{i ( {α}_{x} x + {α}_{y} y )} .\end{matrix}$$

From this it can be concluded that a phase shift α in the input field that is linear in the x and y coordinates can be accommodated by reformulating the dispersion relation in equation (3) as follows:

$${k}_{z} ( x , y , {k}_{x} - {α}_{x} , {k}_{y} - {α}_{y} ) = \sqrt{{k}_{0}^{2} {n ( x , y , {z}_{0} )}^{2} - {( {k}_{x} - {α}_{x} )}^{2} - {( {k}_{y} - {α}_{y} )}^{2}} .$$

Therefore, according to an example, the dispersion relation in (3) can be reformulated using the Floquet theorem. The term within the inverse Fourier Transform is then periodic and can be computed using standard FFT.

In particular, the dispersion relation of the electromagnetic waves 222 within the first section 225 depends on the angle ϕ of the incident electromagnetic waves 222.

In particular, the dispersion relation within the first section 225 is modified by a phase shift in the coordinates parallel to the base plane 234 of the photolithography mask 14.

FIG. 9G illustrates the dependency of the phase shift vector α on the angle ϕ of the incoming electromagnetic waves 222. The angle ϕ can be measured with respect to the normal 254 of the structure plane z₀. The electromagnetic waves 222 are propagated in the direction of the wave vector 256. Let x₀ and x₁ indicate the boundaries of the unit cell in the x-direction, that is the smallest non-periodic subset of the periodic design 292. Then, using the relation

$$sin ϕ = \frac{c}{{x}_{1} - {x}_{0}}$$

the phase difference between x₀ and x₁ can be expressed in terms of ϕ as follows:

$${α}_{x} = \frac{c \cdot 2 π}{λ} = \frac{sin ϕ \cdot 2 π ( {x}_{1} - {x}_{0} )}{λ} .$$

The dependence of α_{y} on the angle of the incoming electromagnetic waves 222 can be computed analogously.

In an example, the photolithography mask 14 is a transmission-based photolithography mask.

In another example, the photolithography mask 14 is a reflection-based photolithography mask, and the second section 227 comprises a multilayer 238 in the form of a stack of optical thin films 240 for reflecting the electromagnetic waves 222.

For reflection-based photolithography masks 14, simulating the propagation of the simulated electromagnetic waves 222 from step a) within the second section 227 of the photolithography mask 14 analytically or numerically can comprise using an analytical description of the electromagnetic wave propagation within the mask carrier 248 and analytically computing the reflection of the electromagnetic waves 222 at the multilayer 238.

Therefore, according to an example, simulating the reflection of the simulated electromagnetic waves 222 from step a) within the multilayer 238 comprises the analytical computation of reflection coefficients at a boundary, e.g., at the boundary plane 232, between the second section 227 and the first section 225 of the photolithography mask 14, the reflection coefficients describing the propagation of the electromagnetic waves 222 within the stack of optical thin films 240 of the multilayer 238. The propagation within the stack of optical thin films 240 of the multilayer 238 corresponds to a reflection at an effective mirror plane 244 at a specific distance from the boundary plane 232.

In particular, the reflection coefficients at the boundary 232 can be computed separately within the structures 226 and outside the structures 226 in the first section 225 of the photolithography mask 14. For example, the reflection coefficients can be computed separately for each medium of the absorber structures and the non-absorber structures of the grating 224 at the location of the boundary plane 232. In this way, the accuracy of the generated aerial image is improved.

In an example, simulating the propagation of the simulated electromagnetic waves 222 within the second section 227 of the photolithography mask 14 comprises applying the reflection coefficients to the electromagnetic waves 222 incident on the boundary 232.

In particular, simulating the reflection of the electromagnetic waves 222 within the multilayer 238 comprises replacing the phase term

$${e}^{i {k}_{z}^{m} ( {k}_{x} , {k}_{y} ) Δ z}$$

in (4) by analytical reflection coefficients rₘ at the boundary plane z₀:

$${E}^{u p} ( x , y , {z}_{0} ) = {\sum }_{m = 1}^{M} {I}_{m}^{{z}_{0}} ( x , y ) {ℱ}^{- 1} \{ {r}_{m} ( {k}_{x} , {k}_{y} ) ℱ \{ {E}^{down} ( x , y , {z}_{0} ) \} \} ,$$

where E^{up} indicates the scalar electric field at the boundary plane z₀ directed towards the structure plane 230 of the photolithography mask 14, and E^{down} indicates the scalar electric field at the boundary plane z₀ directed towards the base plane 234 of the photolithography mask 14. In this way, the computer implemented method for generating an aerial image of a design of a photolithography mask can be applied to reflection-based photolithography masks. In addition, the accuracy of the method is improved.

As shown in the article “Optical properties of a thin-film stack illuminated by a focused field” by S. Kim, Y. Kim and I. Park, Journal of the Optical Society of America A, Vol. 17, No. 8, August 2000, equations 33 to 41, the analytical reflection coefficients rₘ for each of the N optical thin films 240 of the multilayer 238 can be computed for s-polarized waves and p-polarized waves as follows:

$${r}_{j + 1}^{s} = \frac{{Y}_{j} {a}_{11} + {Y}_{j} {Y}_{N + 1} {a}_{12} - {a}_{21} - {Y}_{N + 1} {a}_{22}}{{Y}_{j} {a}_{11} + {Y}_{j} {Y}_{N + 1} {a}_{12} + {a}_{21} + {Y}_{N + 1} {a}_{22}} ,$$

$${r}_{j + 1}^{p} = \frac{- {Y}_{j} {a}_{11} - {Y}_{j} {Y}_{N + 1} {a}_{12} + {a}_{21} + {Y}_{N + 1} {a}_{22}}{{Y}_{j} {a}_{11} {Y}_{j} {Y}_{N + 1} {a}_{12} + {a}_{21} + {Y}_{N + 1} {a}_{22}}$$

where aᵢⱼ are the elements of the characteristic matrix A

$$A = [ \begin{matrix}{a}_{11} & {a}_{12} \\ {a}_{21} & {a}_{22}\end{matrix} ] = {A}_{j + 1} {A}_{j + 2} … {A}_{N} .$$

Here, Aⱼ₊₁ is given by

$${A}_{j + 1} = [ \begin{matrix}cos ( {k}_{0} {h}_{j + 1} ) & - \frac{i sin ( {k}_{0} {h}_{j + 1} )}{{Y}_{j + 1}} \\ - {Y}_{j + 1} i sin ( {k}_{0} {h}_{j + 1} ) & cos ( {k}_{0} {h}_{j + 1} )\end{matrix} ] ,$$

$$where$$

$${h}_{j + 1} = {n}_{j + 1} {d}_{j + 1} cos {θ}_{j + 1}$$

$${Y}_{j + 1} = \sqrt{\frac{{ϵ}_{0}}{{μ}_{0}}} {n}_{j + 1} cos {θ}_{j + 1} for s - polarized waves$$

$${Y}_{j + 1} = \sqrt{\frac{{ϵ}_{0}}{{μ}_{0}}} \frac{{n}_{j + 1}}{cos {θ}_{j + 1}} for p - polarized waves .$$

Here ϵ₀ denotes the vacuum permittivity, μ₀ the vacuum magnetic permeability, nⱼ₊₁ the refractive index of the j+1-th optical thin film 240 and dⱼ₊₁ the thickness of the j+1-th optical thin film 240. Reference is hereby made in full to the aforementioned article, and its disclosure content is included in the description of this invention.

In another example, the reflection of the electromagnetic waves by the multilayer 238 could be computed numerically as follows: In a first step, the electric field at the boundary plane 232 is decomposed in its Fourier Modes. In a second step, for each Fourier mode, the reflected electromagnetic field can be computed using, for example, the transfer matrix method (described in Section 2.2 of the article “Domain Decomposition Method for Maxwell's Equations: Scattering off Periodic Structures,” Achim Schädle, Lin Zschiedrich, Sven Burger, Roland Klose, Frank Schmidt, in arXiv:math/0602179v1). In a third step, the superposition of the reflected Fourier modes yields the reflected electromagnetic waves. Alternatively, a machine learning model can be trained for numerically simulating the propagation of the electromagnetic waves within the second section of the photolithography mask.

FIG. 9H a) to d) illustrate the steps of an example of the not quite rigorous method 200 for generating an aerial image. The design 292 of the photolithography mask 14 comprises elements 294 consisting of polygons in the form of rectangles shown in FIG. 9H a). In a characteristic function step R1, the elements 294 are represented by characteristic functions, e.g., by binary characteristic functions, obtained by any of the methods described above. For example, the elements 294 are represented by binary characteristic functions having the value 1 within the elements 294 and the value 0 outside. Then a spatial analytical Fourier transform is applied to the characteristic functions followed by an inverse FFT for back transformation resulting in band-limited characteristic functions 268. Here, the analytical Fourier transform is only computed for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a band-limited discretized representation of the design 292 of the photolithography mask 14, i.e., band-limited characteristic functions 268 sampled on a sampling grid of low resolution shown in FIG. 9H b). Based on the band-limited characteristic functions 268 a representation of an electromagnetic near field 220 in the form of its amplitude is shown in FIG. 9H c), which is simulated by propagating the simulated electromagnetic waves to a near field plane. Finally, an aerial image 264 shown in FIG. 9H d) is computed by applying a simulation 290 of the imaging process of the photolithography system 10, 10′ within a projection section 19 between the near field plane 252 and a wafer plane 18 to the representation of the electromagnetic near field 220. The imaging process can include resampling of the electromagnetic near field 220 to a grid of higher resolution. By computing the aerial image 264 by applying step R1 and step R3 an accurate aerial image 264 can be simulated for the design 292 of the photolithography mask 14 at low computation times due to the low resolution of the sampling grid. Thus, the computation time for obtaining the aerial image 264 is reduced compared to the simulation of an aerial image 264 by applying a rigorous simulation method (such as RCWA) to the design 292 of the photolithography mask 14 by use of rigorous simulation 295, which requires a sampling grid of high resolution.

Further details of the not quite rigorous method for generating an aerial image are described in the international patent application PCT/EP2023/087651 and in the German patent application 102022135019.3 which are herein incorporated by reference in their entirety.

According to an example, the aerial image simulation method 74 comprises a machine learning model. The aerial image simulation method 74 can, for example, be configured as shown in FIG. 10. The input is a design, in particular a parametric representation 76 of the design. The output is a simulated aerial image 72. A transformation method 88 can, optionally, be used to transform the parametric representation 76 to a standardized representation that is used as input for the following methods 90, 92. For example, a parametric representation 76 containing contours, or nodes and edges, or geometrical shapes, etc. can be transformed, for example, into an image or into a vector format, etc.

A simulation method 90 is used for generating an aerial image from the input design or from the standardized representation of the design. The simulation method 90 can, for example, comprise a physical model of the electromagnetic wave propagation within the photolithography mask, or it can comprise a machine learning model simulating the electromagnetic wave propagation within the photolithography mask. The simulation method 90 can, for example, comprise the TEA method, a rigorous simulation method, a physics-based machine learning model, the NQR method or any other simulation method that can be used to compute an aerial image from a design of a photolithography mask.

The aerial image simulation method 74 can comprise a machine learning model 92. The machine learning model comprises at least one parameter, preferably multiple parameters, e.g., 100.000 parameters. The values of the multiple parameter were determined during training of the machine learning model on training data. The machine learning model 92 can be applied to the result of the simulation method 90. In this way, the machine learning model 92 can improve the accuracy of the simulation method 90. Thus, less accurate or less complex simulations can be used, since these are followed by a machine learning model that improves the accuracy of the simulation result. In addition, a less complex machine learning model 92 can be used, since the input to the machine learning model is already obtained from a physics-based simulation. In this way, the computation time and the accuracy can be improved.

The training of the aerial image simulation method 74 can be carried out in different ways. In a first example, the simulation method 90 is adapted or trained first. In case, the simulation method 90 does not contain a machine learning model, parameters of the simulation method 90 can be adjusted, e.g., using training data or prior knowledge. In case, the simulation method contains a machine learning model, the machine learning model can be trained using training data, e.g., comprising pairs of designs and corresponding aerial images. The following machine learning model 92 can be trained in a following step using pairs comprising the output of the simulation method 90 and corresponding aerial images 54 as training data.

In a second example, the simulation method 90 and the machine learning method 92 can be trained jointly. In this case, weighting the influence of the parameters of the simulation method 90 and of the parameters of the machine learning method 92 in the objective function is beneficial.

In an example, the aerial image simulation method comprises a machine learning model that maps a design to an aerial image. The design can be optimized by solving the optimization problem, e.g., in an iterative way. The deviation of the aerial image from the acquired aerial image can be used in the objective function of the optimization problem.

In another example, a machine learning model can be used to predict a plausible design 62 of the photolithography mask 14 from the acquired aerial image 54, thereby directly solving the optimization problem at a reduced computation time. To this end, for example, machine learning models such as encoder-decoder architectures, e.g., U-Nets, or Vision Transformer architectures can be used. Since the mapping from the acquired aerial image 54 to a plausible design 62 is not injective, i.e., the acquired aerial image 54 can be mapped to different plausible designs 62, the machine learning model can be used to predict a distribution over plausible designs 62. To obtain a distribution over potential plausible designs 62, a diffusion model can, for example, be used.

An optimization problem that minimizes the deviation of the acquired aerial image from the simulated aerial image, wherein the simulated aerial image is obtained using an aerial image simulation method, could be formulated as follows.

Let p denote a set of parameters of a parametric representation of the plausible design. p can also include design parameters such as a mask thickness, refractive indices, etc. The parameters can, for example, be optimized in an iterative way. Let q denote a set of parameters describing the optical system whose application is simulated, in particular illumination parameters, imaging parameters and/or design parameters as described above. To this end, an optimization problem such as the following can be solved:

$${p}_{opt} = arg {min}_{p} χ [ {I}_{acq} , {I}_{s i m} ( p , q ) , p ] .$$

ρₒₚₜ is the target parameter vector that minimizes a difference measure χ between an acquired aerial image l_{acq} and a simulated aerial image Iₛᵢₘ(p, q). χ is an objective function or loss function that defines the optimality condition. It can be linked to a noise model of the acquired aerial image, e.g., for Gaussian i.i.d. noise the L₂-norm can be used. The objective function may also include additional regularization terms as functions of p, in particular to obtain a well-posed objective function, e.g., sparsity constraints.

Different approaches are known for computing the intensity of the simulated aerial image Iₛᵢₘ using partially coherent imaging from an incoming electromagnetic near field corresponding to different illumination angles: for example, the Hopkins approach, the Abbe approach and the local Hopkins approach. The incoming electromagnetic near field can be computed using a near field simulation method such as RCWA, FDTD, TEA or NQR.

The Hopkins approach relies on the observation that for small variations of the incidence angles of the light waves only very small deviations of the intensity, phase and polarization of the light waves can be expected. Thus, a change in the illumination angle approximately only results in a frequency shift of the respective diffraction spectrum of the photolithography mask. The same mask spectrum [symbol] {Eⁱⁿ(x, y, p, q)} of an incoming electromagnetic near field Eⁱⁿ(x, y, p, q) is, therefore, used for all illumination angles with a shift according to the illumination angle:

$${I}^{out} ( {x}^{′} , {y}^{′} , p , q ) = 0.5 {ϵ}^{0} {c}^{0} {\sum }_{i = 1}^{{N}_{Abbe}} \hat{J} ( {f}_{x , i}^{illu} , {f}_{y , i}^{illu} , q ) {\vert {ℱ}^{- 1} \{ ℱ \{ {E}^{in} ( x , y , p , q ) \} ( {f}^{x} - {f}_{x , i}^{illu} , {f}^{y} - {f}_{y , i}^{illu} ) \hat{P} ( {f}^{x} , {f}^{y} , q ) \} \vert}^{2} ,$$

where I^{out}(x′, y′, p, q) indicates the intensity of the simulated aerial image Iₛᵢₘ(p, q), \hat{P}(f^{x}, f^{y}, q) a complex imaging pupil function,

$$\hat{J} ( {f}_{x , i}^{illu} , {f}_{y , i}^{illu} , q )$$

an illumination angle weighting distribution (e.g., with respect to the illumination intensity), ϵ⁰ the electric permittivity, c⁰ the speed of light assuming vacuum,

$${f}_{x , i}^{illu} , {f}_{y , i}^{illu}$$

the illumination angles and N_{Abbe} the number of illumination angles in the illumination angle distribution in the pupil plane.

This approach is simple and fast. For simulations using the thin mask or Kirchhoff approach such as the TEA this assumption is always fulfilled. However, in case that the thickness of the structures on the photolithography mask cannot be neglected anymore and require rigorous electromagnetic field simulations of mask diffraction for varying illumination angles, the Hopkins approach is not sufficiently accurate.

In this case the Abbe approach may be used to accommodate for the non-constant diffraction spectra of the photolithography mask, since the Abbe approach assumes illumination angle dependent diffraction spectra [symbol] {E^{in,i}}, i=1, . . . . N_{Abbe}:

$${I}^{out} ( {x}^{′} , {y}^{′} , p , q ) = 0.5 {ϵ}^{0} {c}^{0} {\sum }_{i = 1}^{{N}_{Abbe}} \hat{J} ( {f}_{x , i}^{illu} , {f}_{y , i}^{illu} , q ) {\vert {ℱ}^{- 1} \{ ℱ \{ {E}^{in , i} ( x , y , p , q ) \} ( {f}^{x} , {f}_{x , i}^{illu} , {f}^{y} , {f}_{y , i}^{illu} ) \hat{P} ( {f}^{x} , {f}^{y} , q ) \} \vert}^{2} .$$

where I^{out}(x′, y′, p, q) indicates the intensity of the simulated aerial image Iₛᵢₘ(p, q). However, the Abbe approach is highly computationally expensive, since an electromagnetic near field has to be simulated for every single illumination angle. Thus, the Abbe approach may not be suitable for use in, e.g., a full chip die-to-die or die-to-database defect detection method.

In order to obtain a fast and accurate simulation method for aerial images of photolithography masks, the local Hopkins approach can be used as disclosed, for example, in US 2007/0253637 A1. The local Hopkins approach is a combination of the Hopkins approach and the Abbe approach based on locally assuming constant diffraction spectra of the photolithography mask. To this end, the source maps are partitioned into a number of segments. For each segment the diffraction spectra are assumed constant, such that only a single diffraction spectrum for each segment has to be simulated. Hence, with the local Hopkins approach, a smaller number of spectra [symbol] {E^{in,j})}, j=1, . . . N_{Hop}, N_{Hop}<<N_{Abbe}, for a subset of selected illumination angles is simulated. For the remaining illumination angles the simulated spectra are shifted according to the illumination angle:

$${I}^{out} ( {x}^{′} , {y}^{′} , p , q ) = 0.5 {ϵ}^{0} {c}^{0} {\sum }_{j = 1}^{{N}_{Hop}} {\sum }_{i = 1}^{{N}_{Abbe , j}} \hat{J} ( {f}_{x , i}^{illu} , {f}_{y , i}^{illu} , q ) {\vert {ℱ}^{- 1} \{ ℱ \{ {E}^{in , j} ( x , y , p , q ) \} ( {f}^{x} - {f}_{x , i , j}^{illu} , {f}^{y} - {f}_{y , i , j}^{illu} ) \hat{P} ( {f}^{x} , {f}^{y} , q ) \} \vert}^{2} ,$$

$$where Δ {f}_{x , i , j}^{illu} = {f}_{x , i}^{illu} - {f}_{x , i , j}^{illu , Hop} and Δ {f}_{y , i , j}^{illu} = {f}_{y , i}^{illu} - {f}_{y , i , j}^{illu , Hop} .$$

where I^{out}(x′, y′, p, q) indicates the intensity of the simulated aerial image Iₛᵢₘ(p, q). The local Hopkins approach requires a careful selection of segments and illumination angles within the segments, for which the diffraction spectra are simulated, as, for example, described in US 2007/0253637 A1.

The Hopkins, Abbe or local Hopkins approach allow to compute the gradient of the objective function with respect to the parameter vector p. Thus, by using one of these approaches to compute the simulated aerial image Iₛᵢₘ(p, q) from the electromagnetic near field in the objective function χ above, the parameters p can be optimized in an iterative way, e.g., by use of gradient descent. Note that, contrary to design parameters (e.g. bias, corner-rounding, etc.), the optimization of optical parameters (e.g. Zernike aberrations) which can be modelled by changes in the pupil function, do not require new simulations of the electromagnetic near field but just a re-evaluation of the Hopkins, Abbe or local Hopkins imaging equations above, thereby simplifying and speeding up the optimization of the parameter vector p.

The optimization problem can comprise a sparsity constraint imposed on one or more parameters of the parameter vector p. Such a sparsity constraint is especially useful if many of the parameters in the solution of the optimization problem are usually 0, e.g., in case the parameters indicate a modification of the underlying design. A sparsity constraint can be implemented using, e.g., L₁-norm regularization. In order to preserve differentiability of the objective function, the L₁-norm can, for example, be approximated using a Huber loss function, which penalizes small parameter deviations quadratically and larger parameter deviations linearly and is differentiable, or a different optimizer such as the fast iterative shrinkage-thresholding algorithm (FISTA). Sparsity constraints can also be implemented using, e.g., Lₚ regularizations for 0≤p≤1.

The resulting optimization problem can be solved in different ways. For example, a downhill simplex approach or a gradient descent approach can be used. Preferably conjugate gradients are used or the Limited-memory Broyden-Fletcher-Goldfarb-Shanno (LBFGS) algorithm. Furthermore, evolutionary algorithms such as simulated annealing could also be used to solve the optimization problem.

In an example of the first embodiment, after step i., one or more regions of interest are identified in the acquired aerial image that contain possible defect candidates, and steps ii. to iv. are only applied to the one or more regions of interest. In this way, the computation time can be strongly reduced. The regions of interest can be determined using fast, less accurate defect detection algorithms. Examples for such methods comprise machine learning models of lower complexity, pattern recognition or template matching methods, filtering approaches, wavelet transforms, image processing methods, etc. These methods can be less accurate, for example by only approximately locating defects (e.g., using bounding boxes) or due to an increased false positive rate. Preferably, fast methods with a low false negative rate are used to determine the regions of interest such that non-defective regions can be reliably excluded from further examination. Alternatively or additionally, regions of interest can be defined by a user. Alternatively or additionally, regions of interest can be derived from the underlying design, e.g., by extracting or excluding specific regions of the photolithography mask or design from defect detection, e.g., depending on the type of structures, properties of the structures, or on spatial properties of the regions.

Within different regions of interest, different preliminary defect detection methods can be used to obtain defect candidates. For example, different properties of the structures can be examined in different regions of the photolithography mask. For example, depending on the structure sizes in a region of interest of the photolithography mask, different minimum defect sizes can be defined and only defect candidates of a larger size can be detected within the corresponding region for further examination by the method according to the invention. Alternatively, within different regions of interest, a method for defect detection according to the invention with region-of-interest-specific parameters can be used. For example, the parameters in step iii. or in step iv. of the method can vary, e.g., the formulation of the optimization problem or rules for discriminating between defects and non-defects. In this way, the sensitivity and specificity of the method can be tuned to different requirements in different regions of interest of the photolithography mask.

A second embodiment of the invention relates to a computer implemented method for training a machine learning model according to any of the examples in the first embodiment, i.e., a machine learning model for mapping an acquired aerial image to a plausible design of the acquired aerial image 54 such that the acquired aerial image is a plausible result of an aerial image simulation method applied to the plausible design, or a machine learning model that is part of an aerial image simulation method as described above.

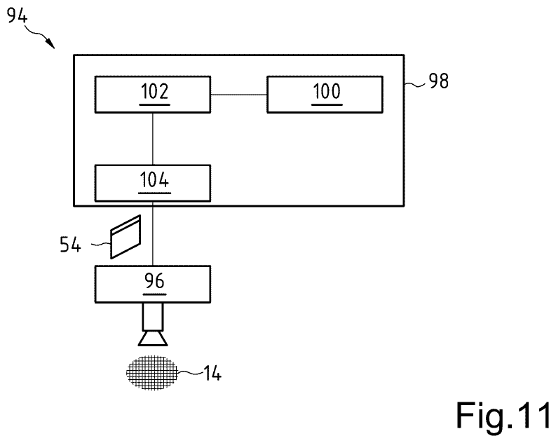

A system 94 for detecting defects 58 in a photolithography mask 14 according to a third embodiment of the invention illustrated in FIG. 11 comprises: an optical system 96 for acquiring an aerial image 54 of the photolithography mask 14; and a data analysis device 98 comprising at least one memory 100 and at least one processor 102 configured to perform the steps of the method 60 for detecting defects 58 in a photolithography mask 14 according to any of the examples or aspects of the first embodiment.

The optical system 96 for acquiring an aerial image 54 of the photolithography mask 14 can comprise an inspection system, an optical mask qualification system, a photolithography system, a metrology system or an aerial image measurement system. The optical system 96 for obtaining an aerial image 54 of the photolithography mask 14 provides the aerial image 54 to the data analysis device 98. The data analysis device 98 includes a processor 102, e.g., implemented as a central processing unit (CPU) or GPU. The processor 102 can receive the aerial image 54 via an interface 104. The processor 102 can load program code from a memory 100, e.g., program code for executing a method for detecting defects 58 as described according to the first embodiment above. The processor 102 can execute the program code.

In some implementations, a system for repairing a photolithography mask can be used to repair the defects in the photolithography mask after the defects are detected using the methods described above. The repair system can be configured to perform an electron beam-induced etching and/or deposition on the mask to repair defects detected by the data analysis device 98. The repair system can include, e.g., an electron source, which emits an electron beam that can be used to perform electron beam-induced etching or deposition on the mask. The repair system can include mechanisms for deflecting, focusing and/or adapting the electron beam. The repair system can be configured such that the electron beam is able to be incident on a defined point of incidence on the mask.

The repair system can include one or more containers for providing one or more deposition gases, which can be guided to the mask via one or more appropriate gas lines. The repair system can also include one or more containers for providing one or more etching gases, which can be provided on the mask via one or more appropriate gas lines. Further, the repair system can include one or more containers for providing one or more additive gases that can be supplied to be added to the one or more deposition gases and/or the one or more etching gases. The repair system can include a user interface to allow an operator to, e.g., operate the repair system and/or read out data. The repair system can also repair other types of objects (e.g., wafers) having integrated circuit patterns.

In some implementations, the apparatus (and its components) can include a light or electromagnetic radiation source to generate light or electromagnetic radiation, an image sensor (e.g., CCD (charged coupled device) or CMOS (complementary metal oxide semiconductor) sensor) having an array of individually addressable sensing elements for capturing images of a sample, and optics (e.g., one or more lenses, mirrors or reflecting surfaces, filters, and/or image stops) to direct and/or focus light or radiation from the one or more light or radiation source to the sample, and from the sample to the image sensor. In some implementations, the apparatus can include a data processor and a storage device. The data processor in the apparatus can be configured to process the data described herein, e.g., according to at least some steps of the methods described herein. The storage device can store at least a part of the instructions comprised in a computer program as described herein, preferably all instructions of the computer program. In some implementations, the apparatus can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The processing of data described in this document, such as detecting defects in a photolithography mask, and training a machine learning model (e.g., to map an acquired aerial image to a plausible design of the acquired aerial image, or to map a design to an aerial image, or to approximately simulate propagation of an incident electromagnetic waves within a section of the photolithography mask), can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Embodiments, examples and aspects of the invention are described by the following clauses:
1. A method 60 for detecting defects 58 in a photolithography mask 14, the method comprising:
   i. Acquiring an aerial image 54 of the photolithography mask 14 using an optical system 96;
   ii. Obtaining an underlying design 64 of the photolithography mask 14;
   iii. Generating a plausible design 62 of the acquired aerial image 54 by solving an optimization problem that minimizes the deviation of a simulated aerial image 72 of the plausible design 62 from the acquired aerial image 54, wherein the simulated aerial image 72 simulates the application of the optical system to the plausible design 62; and
   iv. Detecting defects 58 in the photolithography mask 14 by comparing the underlying design 64 to the plausible design 62.
2. The method of clause 1, wherein the underlying design 64 and the plausible design 62 are represented in a vector format.
3. The method of clause 1, wherein the underlying design 64 and the plausible design 62 are represented by non-binary images.
4. The method of any one of the preceding clauses, wherein the underlying design 64 of the photolithography mask 14 is generated from the acquired aerial image 54.
5. The method of any one of the preceding clauses, wherein the defects 58 in the photolithography mask 14 are detected in step iv. by comparing the underlying design 64 to the plausible design 62 in a mathematical space.
6. The method of any one of the preceding clauses, wherein solving the optimization problem in step iii. comprises applying a machine learning model 70 to the acquired aerial image 54, wherein the machine learning model 70 is trained to map an acquired aerial image 54 to a plausible design 62 of the acquired aerial image 54.
7. The method of any one of the preceding clauses, wherein solving the optimization problem in step iii. comprises minimizing the deviation of a simulated aerial image 72 of the plausible design 62 from the acquired aerial image 54, wherein the plausible design 62 is obtained by modifying the underlying design 64 of the acquired aerial image 54.
8. The method of any one of the preceding clauses, wherein the simulated aerial image 72 of the plausible design 62 is obtained by applying an aerial image simulation method 74 to the plausible design 62.
9. The method of clause 8, wherein the aerial image simulation method 74 comprises the use of a physical model for generating an aerial image from the plausible design 62.
10. The method of clause 8 or 9, wherein the aerial image simulation method 74 comprises a machine learning model 92 that is trained to map a design to an aerial image.
11. The method of clause 8, wherein the aerial image simulation method 74 comprises the use of a physical model for generating an aerial image from the plausible design 62, and wherein a machine learning model 92 is subsequently applied to the generated aerial image to improve its accuracy.
12. The method of clause 8, 9 or 11, wherein the aerial image simulation method 74 generates an aerial image from the plausible design 62 under illumination of the corresponding photolithography mask 14 by incident electromagnetic waves 222 in an optical system and comprises:
   a) Approximately simulating the propagation of the incident electromagnetic waves 222 within a first section 225 of the photolithography mask 14 that comprises multiple structures 226;
   b) Simulating the propagation of the simulated electromagnetic waves 222 from step a within a second section 227 of the photolithography mask 14 analytically or numerically;
   c) Simulating a representation of an electromagnetic near field 220 of the plausible design 62 by propagating the simulated electromagnetic waves from step b to a near field plane 252; and
   d) Generating an aerial image from the plausible design 62 by applying a simulation of an imaging process of the optical system to the representation of the electromagnetic near field 220.
13. The method of clause 12, wherein the propagation of the incident electromagnetic waves within the first section 225 of the photolithography mask 14 in step a is approximately simulated using a Helmholtz equation.
14. The method of clause 12, wherein the propagation of the incident electromagnetic waves within the first section 225 of the photolithography mask 14 in step a is approximately simulated using a machine learning model.
15. The method of clause 13, wherein the Helmholtz equation is approximated using a forward Helmholtz equation.
16. The method of clause 14, wherein the forward Helmholtz equation is solved using a beam propagation method.
17. The method of clause 15, wherein the forward Helmholtz equation is solved using a wave propagation method that approximately describes the propagation of electromagnetic waves 222 through an inhomogeneous medium.
18. The method of any one of the preceding clauses, wherein a parametric representation 76 of the underlying design 64 is optimized by the optimization problem.
19. The method of clause 18, wherein the parametric representation 76 describes structure boundaries of the underlying design 64.
20. The method of clause 18 or 19, wherein the parametric representation 76 comprises contours 78 represented by graphs containing nodes and edges, whose location is optimized by solving the optimization problem.
21. The method of any one of the preceding clauses, wherein the optimization problem comprises parameters that describe a modification of the underlying design 64, and wherein the optimization problem imposes a sparsity constraint on these parameters.
22. The method of any one of the preceding clauses, wherein, after step i., one or more regions of interest are identified in the acquired aerial image 54 that contain possible defect candidates, and wherein steps ii. to iv. are only applied to the one or more regions of interest.
23. A computer implemented method for training a machine learning model to be applied when performing a method according to clause 6 or 11, or which is to be comprised by an aerial image simulation method 74 according to clause 10.
24. A system 94 for detecting defects 58 in a photolithography mask 14, the system 94 comprising:
   i. an optical system 96 for acquiring an aerial image 54 of the photolithography mask 14; and
   ii. a data analysis device 98 comprising at least one memory 100 and at least one processor 102,
      the optical system 96 and the data analysis device 98 being configured to perform the steps of the method 60 for detecting defects 58 in a photolithography mask 14 according to any one of clauses 1 to 22.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

In an aspect, the invention relates to a method 60 for detecting defects 58 in a photolithography mask 14, the method comprising: i. Acquiring an aerial image 54 of the photolithography mask 14 using an optical system 96; ii. Obtaining an underlying design 64 of the photolithography mask 14; iii. Generating a plausible design 62 of the acquired aerial image 54 by solving an optimization problem that minimizes the deviation of a simulated aerial image 72 of the plausible design 62 from the acquired aerial image 54, wherein the simulated aerial image 72 simulates the application of the optical system 96 to the plausible design 62; and iv. Detecting defects 58 in the photolithography mask 14 by comparing the underlying design 64 to the plausible design 62. The invention also relates to a corresponding system for detecting defects.

### REFERENCE NUMBER LIST

10, 10′ Photolithography system
12 Radiation source
14 Photolithography mask
14′ Transmission-based photolithography mask
14″ Reflection-based photolithography mask
16 Illumination optics
17 Projection optics
18 Wafer plane
19 Projection section
54 Aerial image
56 Design
58 Defect
60 Method
62 Plausible design
64 Underlying design
66 Difference
68 Training images
70 Machine learning model
72 Simulated aerial image
74 Aerial image simulation method
76 Parametric representation
77 Initial parametric representation
78 Contour
80 Optimization
81 Deviation
82 Optimized parametric representation
83 Over-parameterized representation
86 Method
88 Transformation method
90 Simulation method
92 Machine learning method
94 System
96 Optical system
98 Data analysis device
100 Memory
102 Processor
104 Interface
200 Not quite rigorous aerial image simulation method
220 Near field
222 Electromagnetic wave
224 Grating
225 First section
226 Structures
227 Second section
228 Non-structures
230 Structure plane
232 Boundary plane
234 Base plane
238 Multilayer
240 Optical thin film
242 Capping layer
244 Effective mirror plane
246 Substrate layer
248 Mask carrier
250 Main propagation direction
252 Near field plane
254 Normal
256 Wave vector
264 Aerial image
268 Band-limited characteristic function
292 Design
294 Elements
295 Rigorous simulation

What is claimed is:

1. A method for detecting defects in a photolithography mask, the method comprising:
i. acquiring an aerial image of the photolithography mask using an optical system;
ii. obtaining an underlying design of the photolithography mask;
iii. generating a plausible design of the acquired aerial image by solving an optimization problem that minimizes the deviation of a simulated aerial image of the plausible design from the acquired aerial image, wherein the simulated aerial image simulates the application of the optical system to the plausible design; and
iv. detecting defects in the photolithography mask by comparing the underlying design to the plausible design.

2. The method of claim 1, wherein the underlying design and the plausible design are represented in a vector format.

3. The method of claim 1, wherein the underlying design and the plausible design are represented by non-binary images.

4. The method of claim 1, wherein the underlying design of the photolithography mask is generated from the acquired aerial image.

5. The method of claim 1, wherein the defects in the photolithography mask are detected in step iv. by comparing the underlying design to the plausible design in a mathematical space.

6. The method of claim 1, wherein solving the optimization problem in step iii. comprises applying a machine learning model to the acquired aerial image, wherein the machine learning model is trained to map an acquired aerial image to a plausible design of the acquired aerial image.

7. The method of claim 1, wherein solving the optimization problem in step iii. comprises minimizing the deviation of a simulated aerial image of the plausible design from the acquired aerial image, wherein the plausible design is obtained by modifying the underlying design of the acquired aerial image.

8. The method of claim 1, wherein the simulated aerial image of the plausible design is obtained by applying an aerial image simulation method to the plausible design.

9. The method of claim 8, wherein the aerial image simulation method comprises the use of a physical model for generating an aerial image from the plausible design.

10. The method of claim 8, wherein the aerial image simulation method comprises applying a machine learning model that is trained to map a design to an aerial image.

11. The method of claim 8, wherein the aerial image simulation method comprises the use of a physical model for generating an aerial image from the plausible design, and wherein a machine learning model is subsequently applied to the generated aerial image to improve its accuracy.

12. The method of claim 8, wherein the aerial image simulation method generates an aerial image from the plausible design under illumination of the corresponding photolithography mask by incident electromagnetic waves in an optical system and comprises:
a) approximately simulating the propagation of the incident electromagnetic waves within a first section of the photolithography mask that comprises multiple structures;
b) simulating the propagation of the simulated electromagnetic waves from step a) within a second section of the photolithography mask analytically or numerically;
c) simulating a representation of an electromagnetic near field of the plausible design by propagating the simulated electromagnetic waves from step b) to a near field plane; and
d) generating an aerial image from the plausible design by applying a simulation of an imaging process of the optical system to the representation of the electromagnetic near field.

13. The method of claim 12, wherein the propagation of the incident electromagnetic waves within the first section of the photolithography mask in step a) is approximately simulated using a Helmholtz equation.

14. The method of claim 12, wherein the propagation of the incident electromagnetic waves within the first section of the photolithography mask in step a) is approximately simulated using a machine learning model.

15. The method of claim 13, wherein the Helmholtz equation is approximated using a forward Helmholtz equation.

16. The method of claim 14, wherein the forward Helmholtz equation is solved using a beam propagation method.

17. The method of claim 15, wherein the forward Helmholtz equation is solved using a wave propagation method that approximately describes the propagation of electromagnetic waves through an inhomogeneous medium.

18. The method of claim 1, wherein a parametric representation of the underlying design is optimized by the optimization problem.

19. The method of claim 18, wherein the parametric representation describes structure boundaries of the underlying design.

20. The method of claim 18, wherein the parametric representation comprises contours represented by graphs containing nodes and edges, whose location is optimized by solving the optimization problem.

21. The method of claim 1, wherein the optimization problem comprises parameters that describe a modification of the underlying design, and wherein the optimization problem imposes a sparsity constraint on these parameters.

22. The method of claim 1, wherein, after step i., one or more regions of interest are identified in the acquired aerial image that contain possible defect candidates, and wherein steps ii. to iv. are only applied to the one or more regions of interest.

23. A computer implemented method for training a machine learning model to be applied when performing a method of claim 6.

24. A computer implemented method for training a machine learning model to be comprised by an aerial image simulation method of claim 10.

25. A system for detecting defects in a photolithography mask, the system comprising:
i. an optical system for acquiring an aerial image of the photolithography mask; and
ii. a data analysis device comprising at least one memory and at least one processor,
the optical system and the data analysis device being configured to perform the steps of the method for detecting defects in a photolithography mask according to claim 1.
